(19) United States
(12) Patent Application Publication
(10) Pub. No.: US 2026/0074164 A1
(43) Pub. Date: Mar. 12, 2026

(54) CHUCKING OF HIGH-WARP SUBSTRATES USING MULTIZONAL CHUCKS

(71) Applicant: Applied Materials, Inc., Santa Clara, CA (US)

(72) Inventors: Pradeep Kumar Subrahmanyan, San Jose, CA (US); D. Jeffrey Lischer, Acton, MA (US); Wonjae Lee, Fremont, CA (US)

(21) Appl. No.: 19/075,600

(22) Filed: Mar. 10, 2025

Related U.S. Application Data
(60) Provisional application No. 63/693,653, filed on Sep. 11, 2024.
(60) Provisional application No. 63/693,634, filed on Sep. 11, 2024.

(51) Int. Cl. H01J 37/32; H01L 21/683

(52) U.S. Cl. CPC H01J 37/32715; H10P 72/722; H01J 2237/2007; H01J 2237/24578

(57) ABSTRACT

Disclosed systems and techniques are directed to improving chucking of substrates in device manufacturing systems. The techniques include identifying deformation of a substrate and applying, based on the identified deformation, a plurality of time-dependent voltage signals to a multizonal chuck to attract the substrate to the multizonal chuck. Each voltage signal of the plurality of time-dependent voltage signals is applied to one or more electrodes of the multizonal chuck. The techniques further include performing one or more processing operations in association with the substrate attracted to the multizonal chuck.

### RELATED APPLICATIONS

This application claims the benefit of the U.S. Provisional Patent Application No. 63/693,634, entitled “WAFER CHUCKING IMPROVEMENT WITH MULTI SCALE WAFER STRESS MODULATION” and U.S. Provisional Patent Application No. 63/693,653, entitled “MODEL BASED CHUCKING FOR HIGH WARP WAFERS, both filed Sep. 11, 2024, the contents of both applications are being incorporated in their entirety by reference herein.

### TECHNICAL FIELD

The disclosure pertains to semiconductor manufacturing, including processing of substrates and devices manufactured thereon.

### BACKGROUND

Modern semiconducting devices, such as processing units, memory devices, light detectors, solar cells, light-emitting semiconductor devices, devices that deploy complementary metal-oxide-semiconductor (CMOS) structures, and the like, are often manufactured on silicon wafers (or other suitable substrates). Wafers may undergo numerous processing operations, such as physical vapor deposition, chemical vapor deposition, etching, photo-masking, polishing, and/or various other operations. In a continuous effort to reduce the cost of semiconductor devices, multi-layer stacks of dies, insulating films, patterned and/or doped semiconducting films, and/or other features are often deposited on a single wafer, resulting in high aspect ratio devices, which are used, e.g., in 3D flash memory devices and other applications. Deposition, patterning, etching, polishing, etc., of stacks of multi-layered structures often result in significant stresses applied to the underlying wafers. Such stresses lead to both an out-of-plane distortion and an in-plane distortion of features supported by the wafers. These distortions result in misalignment of deposited features and can significantly degrade quality of manufactured devices.

### BRIEF DESCRIPTION OF THE DRAWINGS

The present disclosure will be understood more fully from the detailed description given below and from the accompanying drawings of various embodiments of the disclosure.

FIG. 1A illustrates an example sectional view of a processing chamber capable of deploying a chuck to hold a substrate during performance of one or more processing operations, according to at least one embodiment.

FIG. 1B illustrates schematically in-plane and out-of-plane deformation of a substrate placed on a chuck, according to at least one embodiment.

FIG. 2 illustrates schematically example deformation of a substrate as a function of an applied chucking voltage, according to at least one embodiment.

FIG. 3 illustrates an example Zernike polynomial decomposition of one actual deformation (top left) of a substrate, in arbitrary units, into a paraboloid bow deformation (top right), a saddle deformation (bottom left), and a residual deformation, (bottom right), according to at least one embodiment.

FIGS. 4A-E illustrate schematically a process of correcting a substrate deformation using deposition of a stress-compensation layer (SCL) and an application of a stress-modulation beam applied to the SCL, in accordance with at least one embodiment.

FIGS. 5A-5H illustrate example multizonal electrostatic chucks having two or more electrodes that can apply different voltages at different regions of a substrate, according to at least one embodiment: FIG. 5A illustrates a dipolar configuration of a multizonal chuck, in accordance with at least one embodiment; FIG. 5B illustrates a quadrupolar configuration of a multizonal chuck, in accordance with at least one embodiment; FIG. 5C illustrates a quadrupolar configuration with a central electrode, in accordance with at least one embodiment; FIG. 5D illustrates a circular multizonal configuration that includes eleven concentric electrodes and a central electrode, in accordance with at least one embodiment; FIG. 5E illustrates a dipolar configuration with circular electrodes, in accordance with at least one embodiment; FIG. 5F illustrates a quadrupolar configuration with circular electrodes, in accordance with at least one embodiment; FIG. 5G illustrates an example multizonal chuck system in the configuration of FIG. 5C that includes switching circuitry capable of selectively biasing each electrode of the chuck with one of two voltages, in accordance with at least one embodiment; FIG. 5G illustrates an example multizonal chuck system 560 in the configuration of FIG. 5C that includes switching circuitry capable of selectively biasing each electrode of the chuck with one of two voltages, in accordance with at least one embodiment; FIG. 5H illustrates an example of a single-pole double-throw (SPDT) switch 570 that can be used with the multizonal chuck system of FIG. 5G or other similar multizonal chuck systems, in accordance with at least one embodiment. FIG. 5I illustrates a multizonal multipole configuration 570 of chuck 110, in accordance with at least one embodiment. FIG. 5J illustrates another multizonal multipole configuration 570 of chuck 110, in accordance with at least one embodiment.

FIGS. 6A-6H illustrate schematically a process of substrate chucking for various substrate deformations using multizonal chucks of FIGS. 5A-5H, for effective for control of chucking forces, according to at least one embodiment.

FIGS. 7A-7C illustrate a capacitance model that can be used to relate settings of an electrostatic chuck to the clamping pressure of electrostatic forces exerted on a substate held by the electrostatic chuck, according to at least one embodiment.

FIG. 8 is a flowchart illustrating an example method of using multizonal chucks for clamping of substrates without applying excessive forces to the substrates, according to at least one embodiment.

FIG. 9 is a flowchart illustrating an example method of determining settings for beam irradiation, according to at least one embodiment.

FIG. 10A-10B illustrate schematically an irradiation system capable of performing irradiation of stress compensation layers, according to at least one embodiment.

FIG. 11 depicts a block diagram of an example computer system capable of supporting operations of the present disclosure, according to at least one embodiment.

### DETAILED DESCRIPTION

Modern technology often aims to maximize chip area utilization by manufacturing complex three-dimensional devices with vertical stacks of many layers of semiconductor structures. For example, in NAND flash memory devices, lateral relative arrangement (CMOS near Array, or CnA) of memory cells (e.g., floating gate transistors) and peripheral transistors (e.g., CMOS circuitry used to support write/read operations with memory cells) has mostly given way to a vertical arrangement (CMOS under Array, or CuA) in which peripheral CMOS circuitry is disposed under an array of memory cells. In some instances, stacks of layers of memory cells can be manufactured on top of other stacks creating a structure in which precise alignment of various features within the layers is important for proper functioning of the manufactured devices. In one example, a stack of multiple (e.g., tens, hundreds, or more) alternating oxide (O) and nitride (N) layers (e.g., silicon oxide and silicon nitride layers, in one example) can be deposited on top of a substrate, e.g., silicon wafer. Various other layers/films can be deposited on wafers, e.g., polycrystalline silicon layers, carbon and polymer protective films, and/or the like. In another example of a three-dimensional (3D) Dynamic Random-Access Memory (DRAM) manufacturing, a stack of alternating Si₁₋ₓGeₓ (SiGe) alloy layers and silicon (e.g., epitaxial silicon) layers can be deposited on top of a silicon substrate.

Precise alignment (vertical and horizontal) of various features formed on substrates is important for adherence of manufactured devices to technical specifications. On the other hand, features formed on substrates are typically non-uniform and have complex patterns made of different materials. This results in stresses applied to substrates and the ensuing in-plane and out-of-plane deformation. Substrate deformation can cause misalignment of manufactured features and lead to suboptimal or even non-functioning devices. During manufacturing operations (e.g., deposition, etching, particle irradiation, cleaning, and/or the like) substrates are typically held in place using specially designed plates—chucks—that exert vacuum suction forces (in case of vacuum chucks) or electric forces (in case of electrostatic chucks, or ESCs) on the substrates. High-precision feature manufacturing requires secure attachment of substrates to chucks for accurate positioning and temperature control. While forces exerted by chucks on substrates can flatten moderately-deformed substrates, more substantial deformations can impact the ability of chucks to deliver expected performance, e.g., to securely hold substrates in a way that facilitates correct placement and proper alignment of features formed thereon—the functionality referred to as chuckability herein. Factors detrimentally affecting chuckability include substrate warpage, substrate surface roughness, non-uniformity of substrates and features and films deposited thereon (including both the front side and back side of substrates), and/or the like. Sole reliance on forces applied by chucks to flatten strongly warped substrates can result in dielectric breakdown (in electrostatic chucks), stress-caused non-uniformities, increased stresses from lateral forces, e.g., friction, which can cause scratching or cracking of substrates, and/or the like.

Aspects and embodiments of the present disclosure address these and other challenges of the modern semiconductor manufacturing technology by providing for multizonal chucks that improve clamping of substrates. More specifically, instead of using conventional chucks, which apply a uniform voltage difference between the chucks and substrates, a multizonal chuck includes two or more separate electrodes capable of applying different voltages at different regions of the substrate. A “zone,” as used herein, is understood as an azimuthal (circumferential) and/or radial region of a chuck. Correspondingly, a “multizonal” chuck is capable to independently bias multiple azimuthal (circumferential) and/or radial regions of substrates. For example, a dipolar multizonal chuck may be selectively bias a first circumferential zone θ∈(0, π) using one set of electrodes and a second circumferential zone θ∈(π, 2π) using a different set of electrodes. Similarly, a quadrupolar chuck may have four separate sets of electrodes to independently bias a four different circumferential zones θ∈(0, π/2), θ∈(π/2, π), θ∈(π, 3π/2), and θ∈(3π/3,2π). Additionally, some multizonal chucks may also include radially-positioned electrodes, e.g., electrodes positioned at first radial distances from the center of the chuck, r∈(0, R₁), at second radial distances from the center of the chuck, r∈(R₁, R₂), and so on. Furthermore, each zone of the multizonal chuck may include subsets of electrodes, referred to as “poles” capable of independently biasing substrates (e.g., with positive and negative voltages) on a shorter scale. Initially, when a substrate having a bow deformation, a cylindrical deformation, a saddle deformation, and/or the like, is pulled towards the chuck with electric forces, a first voltage signal can be applied to the electrodes of the chuck that make initial contact with the substrate, at the regions of the substrate that are referred to as the primary contact regions herein. The first voltage signal can be gradually increased causing the primary contact regions to make progressively tighter contact with the chuck. As other regions—secondary contact regions—of the deformed substrate come in contact with other electrodes of the chuck, a second voltage signal can be applied to those other electrodes while gradually increasing to ensure secure chucking of the secondary contact regions to the chuck. As secondary contact regions are being pulled closer to the chuck, an out-of-plane deformation of the substrate causes the primary contact regions to slide laterally. To prevent large friction forces (capable of damaging the substrate) from being exerted on the primary contact regions of the substrate, simultaneously with increasing the chucking forces applied at the secondary contact regions, the chucking voltages applied at the primary contact regions can be gradually reduced to an acceptable low voltage value that is still capable to reliably secure the substrate to the chuck. As a final result, the substrate can be held in place with stronger electric forces at the secondary contact regions and weaker electric forces at the primary contact regions. As an example, the primary contact regions of a substrate with a bow deformation can include the center of the substrate and the secondary contact regions can include the edges of the substrate. As another example, the primary contact regions of a substrate with a dome deformation (the inverse bow deformation) can include the edges of the substrate and the secondary contact regions can include the center of the substrate. In substrates with more complicated deformations, additional (third, etc.) voltage signal(s) can be applied to additional electrodes of the chuck. For example, the primary contact regions of a substrate with a saddle deformation can include the downward-facing edges of the substrate, the secondary contact regions can include the center of the substrate, and the tertiary contact regions can include the upward-facing edges of the substrate. Correspondingly, the first voltage signal can be applied to the electrodes of the substrate that come into contact with the downward-facing edges, the second voltage signal can be applied to the electrodes of the substrate that come into contact with the center of the substrate, and the third voltage signal can be applied to the electrodes of the chuck that come into contact with the downward-facing edges voltage. Earlier-applied (e.g., first, second) voltage signals can initially be increased and then decreased as later (e.g., second, third) voltage signals are being applied. As a result, the substrate can ultimately be secured to the chuck with electric forces that are the strongest at the tertiary contact regions (e.g., the downward-facing edges), weaker at the secondary contact regions (e.g., the center region of the substrate), and the weakest at the primary contact regions.

The advantages of the disclosed systems and techniques include (but are not limited to) reliable and consistent chucking (clamping) of substrates without deploying excessive voltages/forces and, therefore, reducing the likelihood and extent of possible scratching, cracking, dielectric breakdown, and/or other damage to the substrates. This improves manufacturing line performance, increases yield, and reduces operational costs of semiconductor device manufacturing.

The disclosed embodiments can be applied to improving chucking of any “wafer” or “substrate,” which refers to any material capable of supporting one or more films, masks, photoresists, layers, etc., that are deposited, formed, etched, or otherwise processed during a fabrication process. For example, a wafer surface on which processing can be performed includes materials such as silicon, silicon oxide, silicon nitride, strained silicon, silicon on insulator, carbon doped silicon oxides, amorphous silicon, doped silicon, germanium, gallium arsenide, glass, sapphire, plastic, and any other materials such as metals, metal nitrides, metal alloys, and other conductive materials, depending on the application. Wafers include, without limitation, semiconductor wafers. Wafers may be exposed to a pretreatment process to polish, etch, reduce, oxidize, hydroxylate, anneal, UV cure, e-beam cure and/or bake the substrate surface. In addition to film processing directly on the surface of the wafer itself, any of the film processing steps disclosed may also be performed on an underlayer formed on the wafer as disclosed in more detail below, and the term “wafer surface” is intended to include such underlayer as the context indicates. Thus, for example, where a film/layer or partial film/layer has been deposited onto a wafer surface, the exposed surface of the newly deposited film/layer becomes the wafer surface. In some embodiments, wafers have a thickness in the range of 0.25 mm to 1.5 mm, or in the range of 0.5 mm to 1.25 mm, in the range of 0.75 mm to 1.0 mm, or more. In some embodiments, wafers have a diameter of about 10 cm, 20 cm, 30 cm, or more.

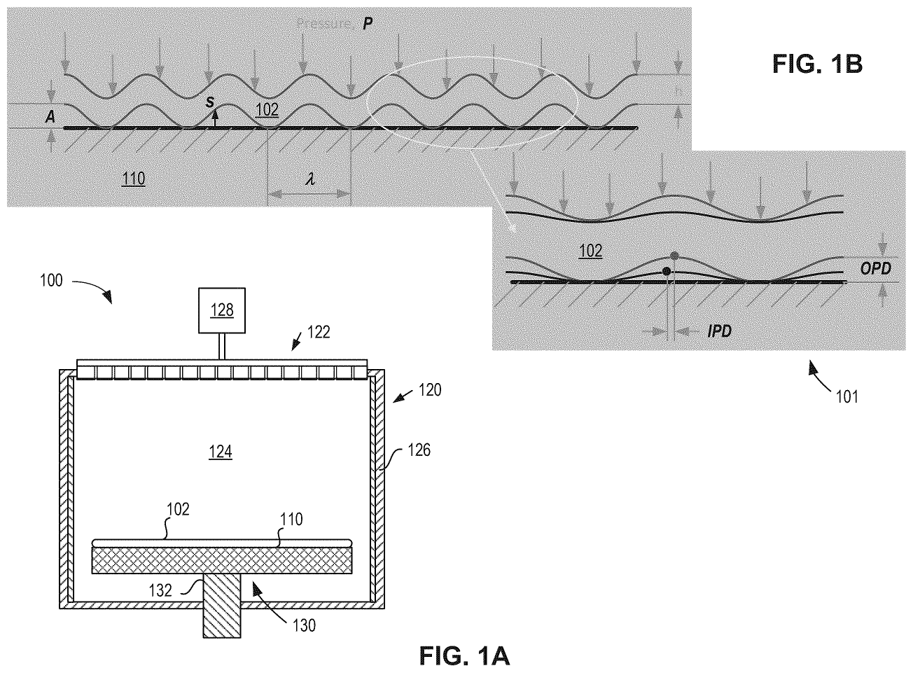

FIG. 1A illustrates an example sectional view of a processing chamber 100 capable of deploying a chuck 110 to hold a substrate 102 during performance of one or more processing operations, according to at least one embodiment. The processing chamber 100 can be a physical vapor deposition (PVD) chamber, a chemical vapor deposition (CVD) chamber, an atomic layer deposition (ALD) chamber, an etch chamber, an epitaxy chamber, a plasma chamber (e.g., a plasma etcher chamber, a plasma etch reactor chamber, a plasma cleaner chamber, etc.) and/or any other chamber of a device manufacturing system.

In one embodiment, the processing chamber 100 includes a chamber body 120, a showerhead 122, and walls 126 that enclose an interior volume 124. A gas source 128 can be coupled to the processing chamber 100 to provide process and/or cleaning gases to the interior volume 124 through the showerhead 122. A heater assembly 130 can be disposed in the interior volume 124 of the processing chamber 100, e.g., below the showerhead 122. The heater assembly 130 can include a chuck 110 that securely holds substrate 102 during processing. The chuck 110 can be attached to the end of a shaft 132 that is coupled to the chamber body 120 via a flange. The chuck 110 can further include mesas (e.g., dimples or bumps). The chuck 110 can additionally include electrodes and wires, for example, tungsten wires (not shown), embedded within the heater material of the chuck 110.

FIG. 1B illustrates schematically in-plane and out-of-plane deformation of a substrate placed on a chuck, according to at least one embodiment. As illustrated, substrate 102 is attracted to chuck 110 by application of a downward clamping pressure P, e.g., caused by electrostatic forces of attraction to chuck 110 (e.g., one or more electrodes built into the chuck). As illustrated, substrate 102 of thickness h has a single-harmonic deformation with wavelength λ and amplitude A, such that the profile of deformation of substrate 102 has the form (the amount of deformation is exaggerated in FIG. 1B),

$$s ( x ) = \frac{A}{2} ( 1 + cos ( \frac{2 π x}{λ} ) ) ,$$

where s(x) stands for a gap between a surface of substrate 102 (e.g., the bottom surface) and a reference surface (e.g., the surface of chuck 110) as a function of a coordinate x along the substrate.

As illustrated with the blowout portion 101 in FIG. 1B, various points of substrate 102 experience both an in-plane deformation (IPD) and an out-of-plane deformation (OPD), which are related through the substrate curvature expressed in the s(x) dependence. OPD affects chuckability (with substrates having a large OPD having no or reduced chuckability) whereas IPD affects alignment of features deposited, formed, etched, or otherwise manufactured on substrate 102.

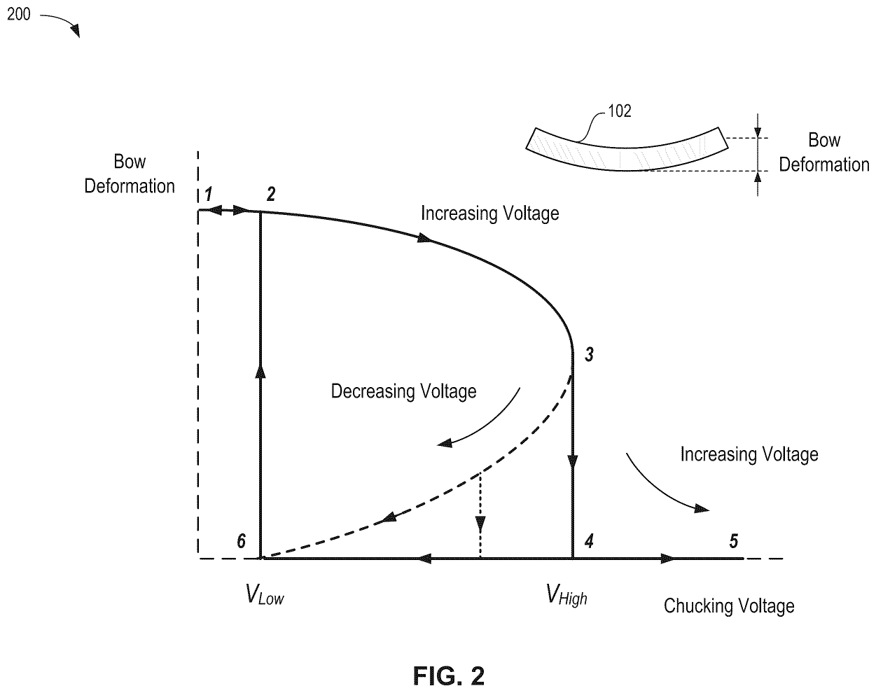

FIG. 2 illustrates schematically example deformation 200 of a substrate as a function of an applied chucking voltage, according to at least one embodiment. Deformation 200 is illustrated for a bow (e.g., approximately parabolic) deformation and includes several portions illustrated by the respective curves in FIG. 2 (see, e.g., Daniel L. Goodman, “Effect of wafer bow on electrostatic chucking and back side gas cooling,” J. Appl. Phys. 104, 124902 (2008)). At zero chucking voltage, the substrate can have some bow deformation corresponding to point 1. As the chucking voltage increases along the portion 1-2-3 towards the value V_{High}, the substrate's deformation continuously decreases. Substrate's deformation along the portion 1-2-3 is reversible, meaning that decreasing the chucking voltage at any point along this portion increases the deformation. At point 3, further increase of the chucking voltage causes the wafer to discontinuously flatten (collapse), as illustrated with the portion 3-4-5. Decreasing the voltage at point 3, however, does not return the substrate's deformation to the portion 1-2-3. Instead, the deformation follows the metastable portion 3-6 (indicated with the dashed line) where the substrate's deformation continues to decrease despite decreased chucking voltage. Along this unstable portion, various mechanical perturbations cause the substrate to collapse into a flat state on the chuck (as depicted with the dotted arrow in FIG. 2) and then follow the line 4-6. At point 6, corresponding to a voltage value V_{Low}, the chucking forces are no longer sufficient to maintain the substrate flat, its deformation springs back discontinuously to the portion 1-2-3. Further decrease of the chucking voltage then returns the substrate's deformation to the initial point 1. Accordingly, the substrate's deformation displays hysteretic behavior between voltage values V_{Low} and V_{High}. This hysteresis can be used to facilitate efficient chucking without applying excessive voltages, as disclosed in more detail below.

In some embodiments, the substrate can undergo a measurement of its height profile s(\vec{r}), where r stands for the Cartesian coordinates x, y, polar coordinates r, φ or some other suitable set of coordinates (e.g., elliptic coordinates). The profile s(\vec{r}) can refer to the vertical coordinate of the bottom surface of substrate 102 (with reference to FIG. 1B), the top surface of substrate 102 or to some other reference surface. In some embodiments, height profile s(\vec{r}) of substrate 102 can be measured using optical metrology (e.g., optical interferometry) techniques. In some embodiments, the height profile s(\vec{r}) can be measured after one or more features are deposited on substrate 102.

The height profile s(\vec{r}) can then be represented via a number of parameters that qualitatively and quantitatively characterize geometry of the wafer deformation, e.g., a set of Zernike (or a similar set of) polynomials, s(\vec{r})=ΣⱼAⱼZⱼ(\vec{r}), a set of Fourier harmonics, or a combination of Zernike polynomials and Fourier harmonics. Consecutive coefficients A₁, A₂, A₃, A₄ . . . represent weights of specific geometric features (elemental deformations) of substrate 102 described by the corresponding Zernike polynomials Z₁(r, φ), Z₂(r, φ), Z₃(r, φ), Z₄(r, φ) . . . (Herein, the Noll indexing scheme for the Zernike polynomials is being referenced.)

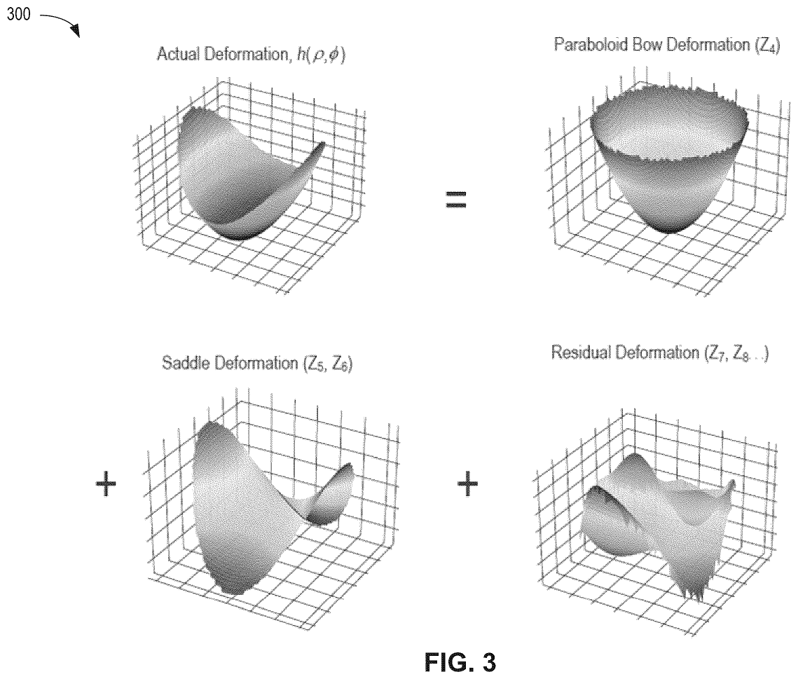

FIG. 3 illustrates an example Zernike polynomial decomposition 300 of one actual deformation s(r, φ) (top left) of a substrate (e.g., substrate 102), in arbitrary units, into a paraboloid bow deformation A₄Z₄(r, φ) (top right), a saddle deformation A₅Z₅(r, φ)+A₆Z₆(r, φ) (bottom left), and a residual deformation, sᵣₑₛ(r, φ) (bottom right), according to at least one embodiment.

The first three coefficients are of less interest as they describe a uniform shift of substrate 102 (coefficient A₁, associated with the Z₁(r, φ)=1 polynomial), a deformation-free x-tilt that amounts to a rotation around the y-axis (coefficient A₂, associated with the Z₂(r, φ)=2r cos φ polynomial), and a deformation-free x-tilt that amounts to a rotation around the x-axis (coefficient A₃, associated with the Z₃(r, φ)=2r sin φ polynomial) that can be eliminated by a realignment of the coordinate axes. The fourth coefficient A₄ is associated with Z₄(r, φ)=\sqrt{3}(2r²−1) and characterizes an isotropic paraboloid deformation (“bow”). The fifth A₅ and the sixth A₆ coefficients are associated with Z₅(r, φ)=\sqrt{6}r² sin 2φ and Z₆(r, φ)=\sqrt{6} r² cos 2φ polynomials, respectively, and characterize a saddle-type deformation. The A₅ coefficient characterizes a saddle shape that curves up (A₅>0) or down (A₅<0) along the diagonal y=x and curves down (A₅>0) or up (A₅<0) along the diagonal y=−x. The A₆ coefficient characterizes a saddle shape that curves up (A₆>0) or down (A₆<0) along the x-axis and curves down (A₆>0) or up (A₆<0) along the y-axis. The higher coefficients A₇, A₈, etc., characterize progressively faster variations of the wafer deformation s(r, φ) along the radial direction, along the azimuthal direction, or both and collectively represent a residual deformation,

$${s}_{r e s} ( r , ϕ ) = s ( r , ϕ ) - {\sum }_{j = 4}^{6} {A}_{j} {Z}_{j} ( r , ϕ ) .$$

Optical inspection followed by Zernike polynomial decomposition determines the parabolic (uniform or global) bow deformation A₄. Parabolic bow deformation can be eliminated by deposition of a stress compensation layer (SCL) on substrate 102. The remaining non-parabolic deformation can then be corrected by application of a stress-modulation beam with local (position-dependent) doses of stress-modulation particles.

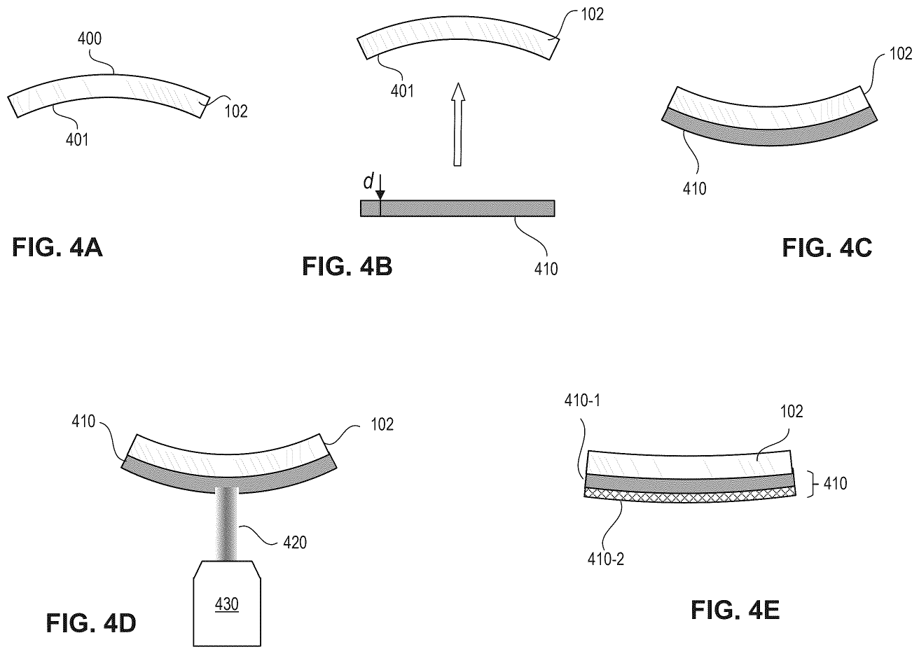

FIGS. 4A-E illustrate schematically a process of correcting a substrate deformation using deposition of an SCL and an application of a stress-modulation beam applied to the SCL, according to at least one embodiment. FIG. 4A depicts substrate 102 having a deformation, which can include a paraboloid bow deformation (with negative coefficient A₄<0, as illustrated) and can further include other deformations, including saddle deformation, residual deformation, etc. The wafer's front side 400 can include any number of features, e.g., deposition and/or etching patterns, a stack of layers/films, and/or any other structures. FIG. 4B illustrates deposition of an SCL 410 on the back side 401 of substrate 102. SCL 410 can be (or include) a silicon nitride layer or some other type of material. In some embodiments, SCL 410 can include layers of multiple materials. In some embodiments, a material of SCL 410 can be selected in view of the sign of coefficient A₄.

For example, for a negative bow, A₄<0, SCL 410 can be selected to have a compressive stress (as illustrated in FIGS. 4B-4E). Conversely, for a positive bow, A₄>0, SCL 410 can be selected to have a tensile stress. SCL 410 can be deposited using any suitable deposition techniques including physical vapor deposition (e.g., sputtering), chemical vapor deposition (e.g., plasma-assisted deposition), epitaxy, exfoliation, and/or the like. SCL 410 can be deposited using any suitable deposition techniques including physical vapor deposition (e.g., sputtering), chemical vapor deposition (e.g., plasma-assisted deposition), epitaxy, exfoliation, and/or the like. Deposition can be performed at room temperature or at temperatures different from room temperature (e.g., at an elevated temperature). In some embodiments, thickness d of SCL 410 can be selected to overcorrect the wafer deformation to some degree, e.g., as illustrated in FIG. 4C where a positive paraboloid is overcorrected to a negative paraboloid bow. The thickness-dependent paraboloid bow correction A_{corr}(d) changes wafer deformation from s(r, φ) to s_{corr}(r, φ):

$${s}_{c o r r} ( r , ϕ ) = s ( r , ϕ ) + {A}_{c o r r} ( d ) \cdot {Z}_{4} ( r , ϕ ) .$$

The degree of overcorrection can be chosen in conjunction with a type and parameters (e.g., energy, dose, etc.) of a specific stress-modulation beam 420 to be used on SCL 410. The overcorrection can make the combined structure of substrate 102 and SCL 410 susceptible to further control of stress (and thus control of deformation of the wafer h_{corr}(r, φ)). As illustrated in FIG. 4D, collimating and focusing column 430 can generate a stress-modulation beam 420 that strikes SCL 410 and changes its elastic properties, e.g., by creating vacancies, breaking crystal bonds, depositing ions, and/or via any other applicable mechanisms. Stress-modulation beam 420 can carry photons, electrons, silicon ions, phosphorus ions, argon ions, neon ions, xenon ions, krypton ions, and/or the like. In some embodiments, the energy and type of ions in stress-modulation beam 420 can be selected to limit the implanted ions to the volume of SCL 410 without allowing the ions to reach substrate 102 (and/or any layers/films deposited on substrate 102). Ions that lodge in SCL 410 create substitution defects therein. Additionally, the ions leave a trail of vacancy defects along paths of propagation in SCL 410. The substitution defects and/or vacancies mitigate (e.g., reduce) stress in SCL 410 and can reduce the degree of stress overcorrection caused by the SCL deposition. This causes the combination of substrate 102 and SCL 410 to flatten.

In some embodiments, the number of ions ΔNᵢ deposited per small area ΔA=ΔxΔy (or the total amount of photon energy applied to this area) of substrate 102 can be determined using simulations (performed as described in more detail below) based on the local value of the corrected deformation s_{corr}(r, φ), which may include a saddle deformation, a residual deformation, and the part of the paraboloid bow deformation A_{corr}(d)+A₄ that has been overcorrected by the deposition of stress-compensation layer 420. The target local density n(x, y)=ΔNᵢ/ΔxΔy of the ions can be delivered by controlling the scanning velocity v of stress-modulation beam 420. In some embodiments, stress-modulation beam 420 has a profile that can be approximated with a Gaussian function, e.g., the ion flux j(ρ)=j₀ exp(−x²/a²−y²/b²), where x and y are Cartesian coordinates, j₀ is the maximum ion flux at the center of the beam, and a and b is are characteristic spreads of the beam along the x-axis and y-axis, respectively.

Correspondingly, a point that is located at distance y from the path of the center of the beam receives an ion dose that includes the following number of ions:

$$\frac{Δ {N}_{i}}{Δ x Δ y} = \frac{{j}_{0}}{v} {\int }_{- ∞}^{∞} d x {e}^{- {x}^{2} / {a}^{2} - {y}^{2} / {b}^{2}} = \frac{{j}_{0} \sqrt{π}}{v a} {e}^{- {y}^{2} / {b}^{2}} .$$

Correspondingly, by reducing the scanning velocity v, the number of ions received by various regions of SCL 410 can be increased, and vice versa. Additionally, stress-modulation beam 420 can perform multiple scans with different offsets y so that various points of SCL 410 receive multiple doses of ions with different factors e^{-y}^{²}^{/b}^{²} that can average to a target dose. For example, after n passes of stress-modulation beam 420, each made with a respective velocity vₖ at a different distance yₖ from the center of the beam to the area ΔxΔy, the total dose of ions (or amount of electromagnetic radiation) received by this area will be

$$n ( x , y ) = \frac{Δ {N}_{i}}{Δ x Δ y} {\vert}_{total} = {j}_{0} \sqrt{π} {\sum }_{k = 1}^{n} \frac{{e}^{- {y}_{k}^{2} / {b}^{2}}}{a {v}_{k}} .$$

As illustrated in FIG. 4E, presence of a stress-mitigated portion 410-2 of SCL 410 results in a significant mitigation of deformation of substrate 102, including saddle and residual deformations.

In some embodiments, the intensity and/or total amount of irradiation per various areas of substrate 102 can be determined using simulations, e.g., Monte Carlo simulations. The Monte Carlo simulations can be performed for a film made of the actual material used in SCL deposition and having a specific thickness d. An initial Monte Carlo simulation can be performed for specific baseline (default) conditions of the particle irradiation (e.g., default settings of an ion implantation apparatus). The baseline conditions can include a default type of particles, a default energy of the particles, a default dose of particles to be applied to SCL 410 (e.g., a default velocity of scanning and a default scanning pattern), and the like. The baseline conditions can subsequently be modified (e.g., optimized) using the Monte Carlo simulations. The Monte Carlo simulations can use calibration data collected (measured) for actual particle irradiation performed for various ion/photon/electron energies, types of ions, types and materials of masks/layers, angles of particle incidence on the films, and/or the like.

In some embodiments, the implantation map n(\vec{r}) can be computed using an influence function G(\vec{r}; \vec{r}′) that characterizes a response (e.g., deformation) at a point \vec{r} of the wafer as caused by a point-like force applied at another point \vec{r}′ of substrate 102. In some embodiments, the influence function G(\vec{r}; \vec{r}′), also known as the Green's function, can be determined from computational simulations or from analytical calculations. In some embodiments, the influence function can be determined from one or more experiments, which can include performing ion implantation into a film deposited on a reference wafer.

In some embodiments, substrate deformation s(\vec{r})=s_{quad}(\vec{r})+sᵣₑₛ(\vec{r}) can be represented (decomposed) as a combination of a quadratic s_{quad}(\vec{r}) and residual (non-quadratic) sᵣₑₛ(\vec{r}) contributions. The quadratic deformation can include a parabolic (paraboloid) part, which has the complete axial symmetry, and a saddle part. The thickness d of SCL 410 can be computed (or empirically determined) in such a way that the mask is to apply a desired target stress to substrate 102. To eliminate a non-uniform saddle deformation, SCL 410 can be of such thickness/material that turns the saddle deformation into a cylindrical deformation having a definite sign throughout the area of substrate 102. The uniform-sign cylindrical deformation (as well as a residual higher-order non-quadratic deformation) can then be mitigated with irradiation by stress-modulation beam 420. In some embodiments, a cylindrical decomposition is not unique and can be either positive (upward-facing cylindrical deformation) or negative (downward-facing cylindrical deformation). Both decompositions can be analyzed and a decomposition that enables a more effective stress mitigation can be selected. For example, a decomposition that is characterized by a smaller parabolic bow deformation can be selected. The parabolic bow deformation can be mitigated using a choice of SCL 410 (e.g., type and thickness) while the remaining cylindrical deformation (and the higher-order residual deformation) can be addressed by appropriately selected ion or photon irradiation doses n(\vec{r}).

In some embodiments, mitigation of a cylindrical deformation or a saddle deformation can include identifying principal axes (directions) of the cylinder/saddle and a magnitude of the cylindric/saddle deformation and directing stress-modulation beam 420 into appropriately selected edge regions of SCL 410. For example, individual edge regions to which the stress-modulation beam 420 is directed can have a width that is at or below 30% of a diameter of substrate 102. Residual higher-order (ripple) deformations can then be mitigated with further irradiation into the area of SCL 410.

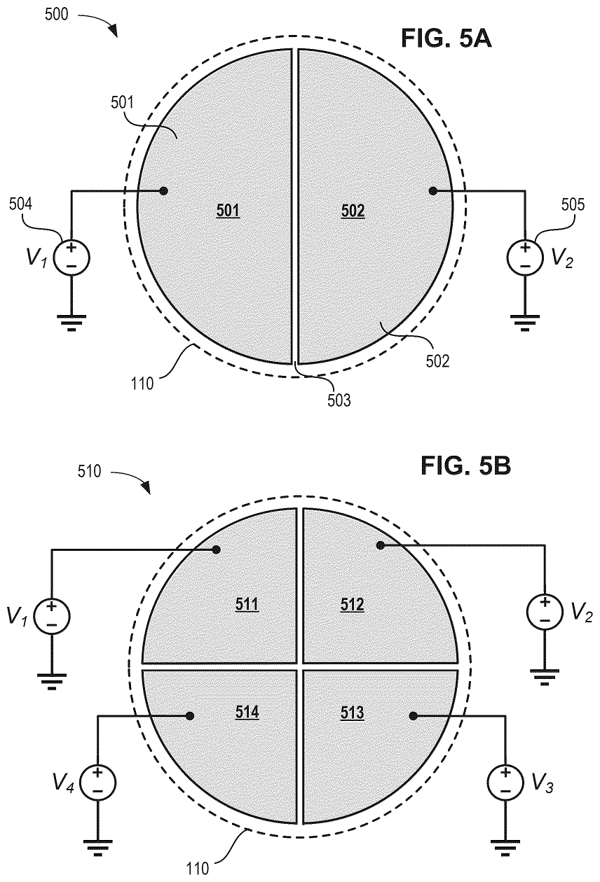

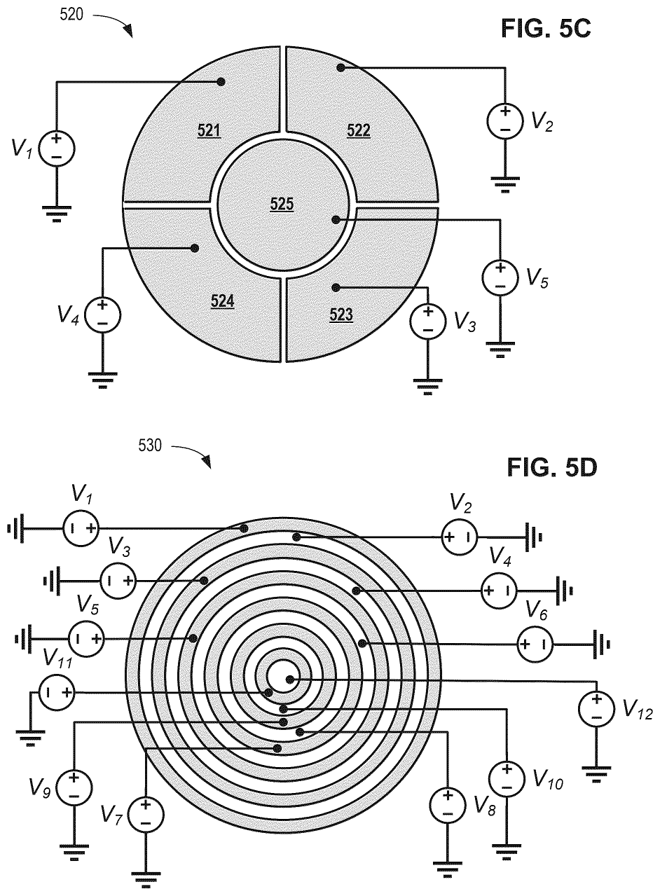

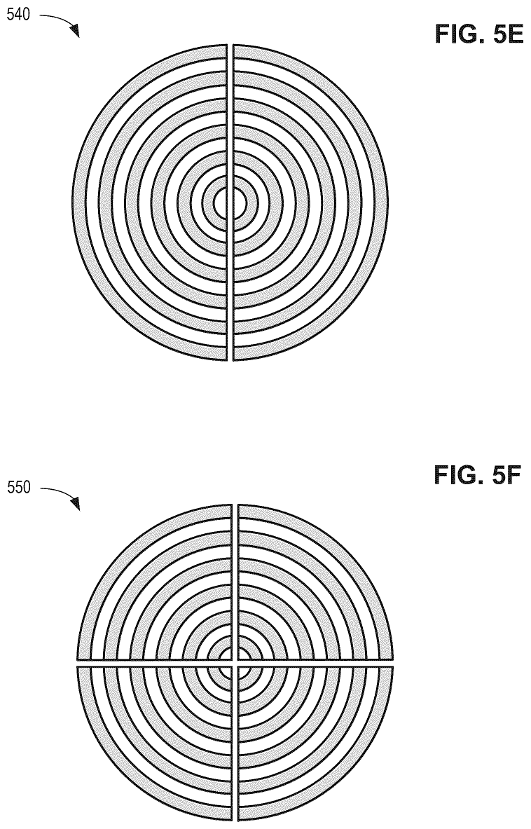

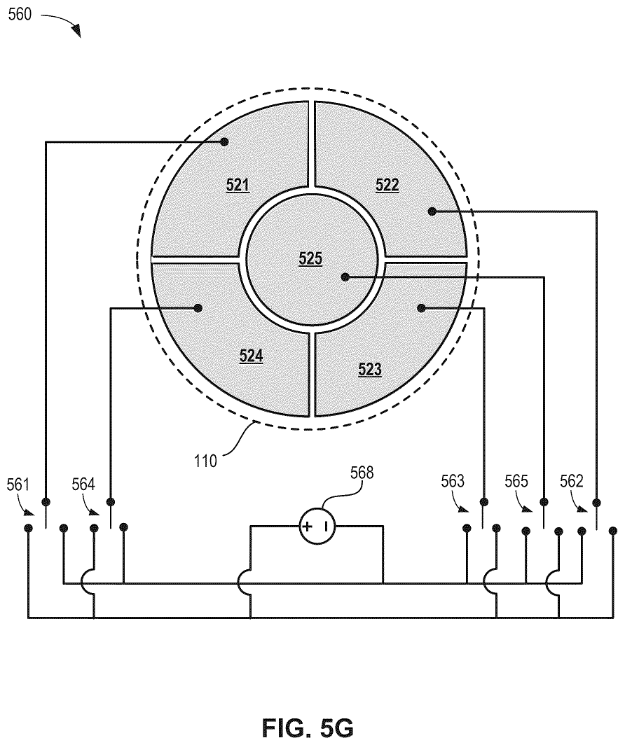

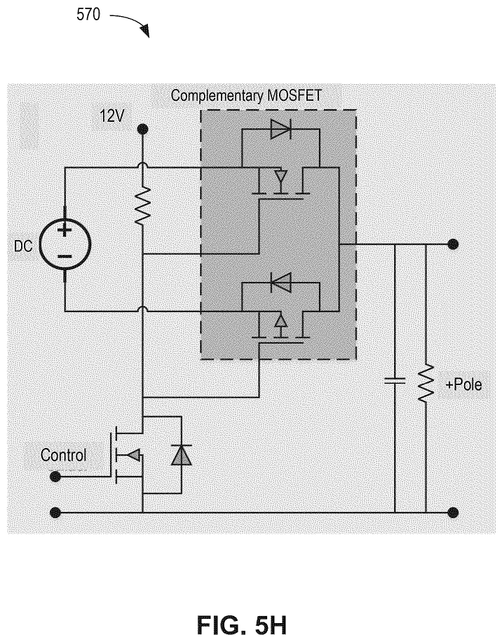

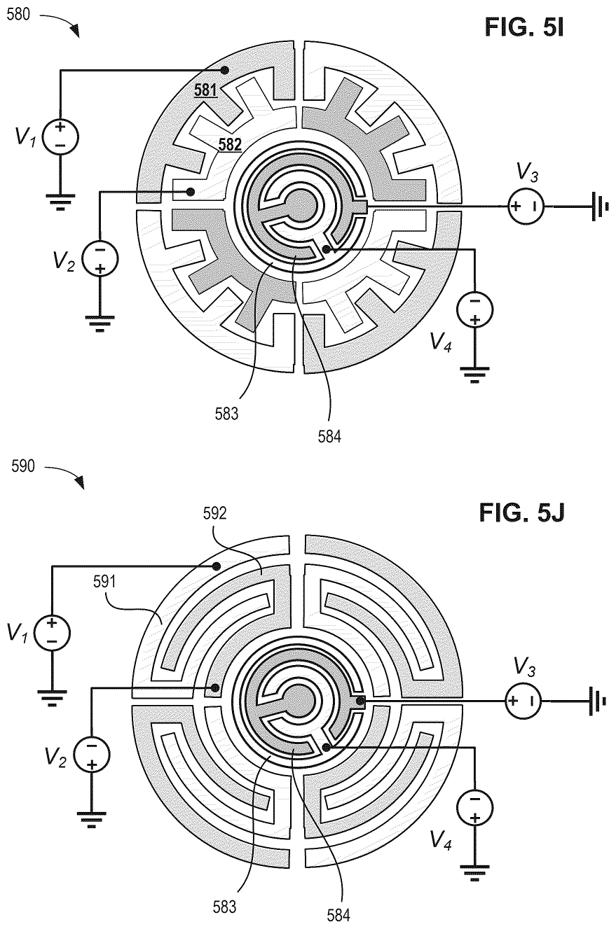

FIGS. 5A-5F illustrate example multizonal electrostatic chucks having two or more electrodes that can apply different voltages at different regions of a substrate, in accordance with at least one embodiment. Electrostatic chucks (ESC) illustrated in FIGS. 5A-5F can include Coulombic chucks (e.g., aluminum oxide chucks), Johnsen-Rahbek chucks (e.g., aluminum nitride chucks, which allow leakage currents to flow through the chuck's body), and/or other suitable chucks. FIG. 5A illustrates a dipolar configuration 500 of a multizonal chuck 110, in accordance with at least one embodiment. The chuck includes two semi-circular electrodes 501 and 502 electrically insulated by a spacing 503. Each of the electrodes 501 and 502 can be independently biased by voltages V₁ and V₂ applied by voltage sources 504 and 505, respectively. Chucks in the dipolar configuration 500 can be used for control of chucking forces applied to substrates with cylindrical deformation.

FIG. 5B illustrates a quadrupolar configuration 510 of multizonal chuck 110, in accordance with at least one embodiment. The chuck includes four azimuthally (circumferentially) isolated quarter-circular electrodes 511, 512, 513, and 514 with each of the electrodes capable of being independently biased by voltages V₁, V₂, V₃, and V₄ applied by the respective voltage sources. Chucks in the quadrupolar configuration 510 can be used for control of chucking forces applied to substrates with saddle deformation.

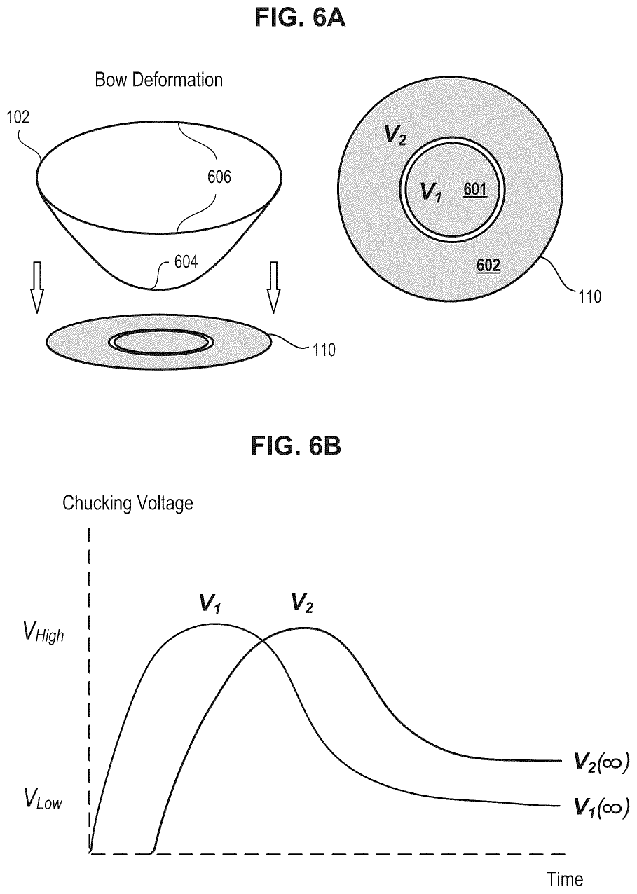

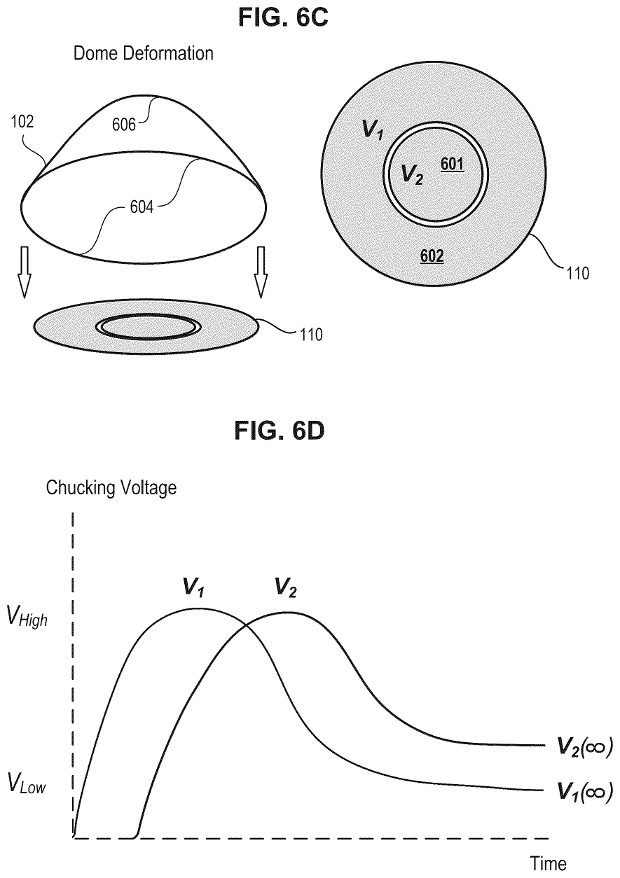

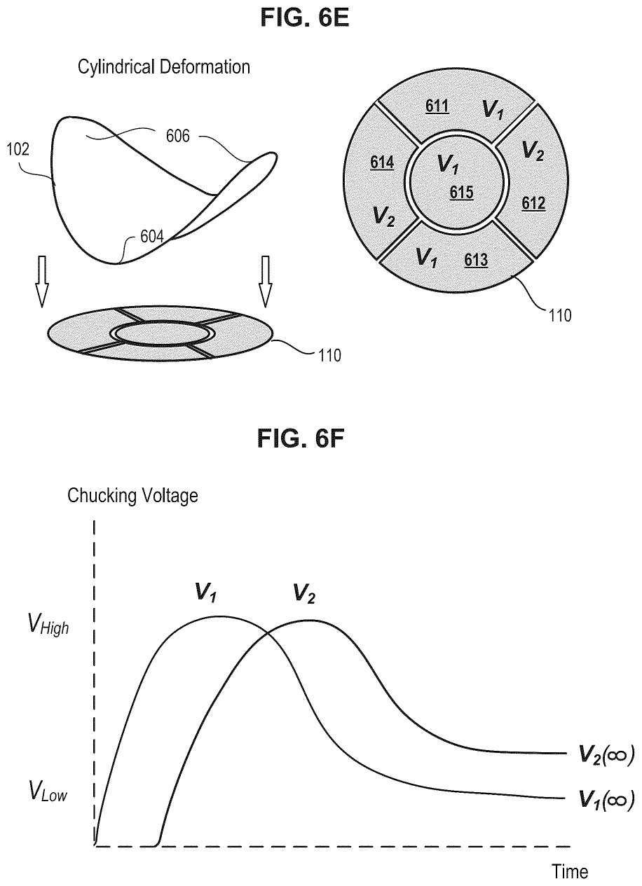

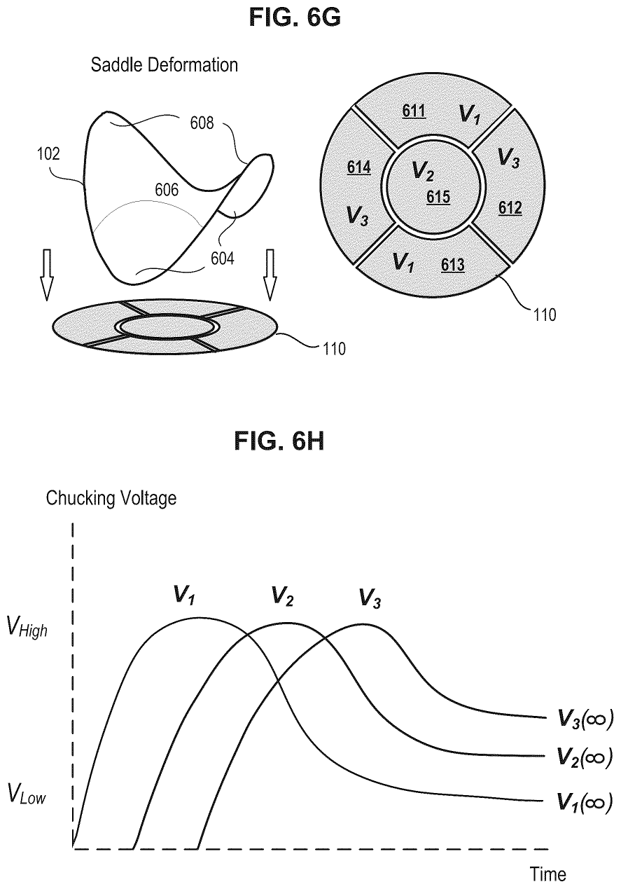

FIG. 5C illustrates a quadrupolar configuration 520 with a central electrode, in accordance with at least one embodiment. The chuck includes four azimuthally (circumferentially) isolated edge electrodes 521, 522, 523, and 524 and a central electrode 525 with each of the electrodes capable of being independently biased by voltages V₁, V₂, V₃, V₄, and V₅ applied by the respective voltage sources. Chucks in the quadrupolar configuration 520 with a central electrode can be used for control of chucking forces applied to substrates with bow-shaped deformation, dome-shaped deformation, cylindrical deformation, and saddle deformation, e.g., as disclosed in more detail below in conjunction with FIGS. 6E-6H below.

FIG. 5D illustrates a circular multizonal configuration 530 that includes eleven concentric electrodes and a central electrode, in accordance with at least one embodiment. Each of the electrodes is capable of being independently biased by voltages V₁ . . . V₁₂ applied by the respective voltage sources Although twelve electrodes are illustrated for the circular multizonal configuration 530 in FIG. 5D, the number of electrodes can be more or less than twelve, in other embodiments. Some of the electrodes shown in FIG. 5D can be permanently connected to wires built into the (insulating) material of the chuck or using circuitry located at the bottom side of the chuck. Concentric electrodes in the circular multizonal configuration 530 can be used for fine radial control of chucking forces applied to a substrate with a bow-shaped or dome-shaped deformation, as disclosed in more detail below in conjunction with FIGS. 6A-6D below.

FIG. 5E illustrates a dipolar configuration 540 with circular electrodes, in accordance with at least one embodiment. Each of the twenty-four example electrodes shown is potentially capable of being independently biased by corresponding voltage sources (not shown in FIG. 5E for conciseness and ease of viewing). Chucks in the configuration 540 can be used for control of chucking forces applied to substrates with bow-shaped deformation, dome-shaped deformation, and/or cylindrical deformation.

FIG. 5F illustrates a quadrupolar configuration 550 with circular electrodes, in accordance with at least one embodiment. Each of the forty-eight azimuthally (circumferentially) isolated example electrodes shown is potentially capable of being independently biased by corresponding voltage sources (not shown in FIG. 5F for conciseness and ease of viewing). Chucks in the configuration 550 can be used for control of chucking forces applied to substrates with bow-shaped deformation, dome-shaped deformation, cylindrical deformation, saddle deformation, and/or other (more complex) types of substrate deformation.

Multizonal configurations shown in FIGS. 5A-5F should be considered as illustrative examples. A practically unlimited number of various multizonal configurations can be used (e.g., configurations with more than four azimuthal segments, e.g., an octupolar configuration with eight azimuthal segments, etc.) with electrostatic chucks.

FIG. 5G illustrates an example multizonal chuck system 560 in the configuration of FIG. 5C that includes switching circuitry capable of selectively biasing each electrode of the chuck with one of two voltages, in accordance with at least one embodiment. Multizonal chuck system 560 includes five single-pole double-throw (SPDT) switches 561, 562, 563, 564, and 565 that selectively connect the respective electrodes 521, 522, 523, 524, and 525 to a dc voltage source 568.

FIG. 5H illustrates an example of a single-pole double-throw (SPDT) switch 570 that can be used with multizonal chuck system 560 or other similar multizonal chuck systems, in accordance with at least one embodiment. SPDT switch 570 can be deployed as any, some, or all SPDT switches 561-565 of multizonal chuck system 560 of FIG. 5G. SPDT switch 570 can be based on one or more complementary metal-semiconductor field-effect transistors (MOSFETs), as illustrated.

Although each zone in FIGS. 5A-5H is shown (for ease of viewing) to include one electrode, any zone can have multiple poles, e.g., electrodes overlapping (interlaced) along both radial and azimuthal directions. Such multiple poles within a given zone can be used in various, e.g., non-plasma, applications. FIGS. 5A-5H illustrate such multizonal multipole chuck. FIG. 5I illustrates a multizonal multipole configuration 580 of chuck 110, in accordance with at least one embodiment. The chuck includes four quarter-circle zones and a central zone. Each of the zone includes two electrodes (poles) that can be biased independently, e.g., with positive or negative voltages. As shown, electrodes 581 and 582 are located in one of the zones. Electrodes 581 and 582 partially overlap with radial interlaced spikes connected with azimuthal connectors. (Other quarter-circle zones may be similarly biased but not annotated for conciseness.) Also shown are two electrodes (poles) 583 and 584 of the central zone, which include interlaced concentric circles connected with radial connectors. FIG. 5J illustrates another multizonal multipole configuration 590 of chuck 110, in accordance with at least one embodiment. As shown, electrodes 591 and 592 partially overlap with azimuthal interlaced spikes connected with radial connectors.

FIGS. 6A-6H illustrate schematically a process of substrate chucking for various substrate deformations using multizonal chucks of FIGS. 5A-5H, for effective control of chucking forces, according to at least one embodiment. FIG. 6A illustrates schematically substrate 102 having a bow deformation being chucked by a chuck in configuration 530 (illustrated in FIG. 5D) configured with two electrodes—an inner electrode 601 and an outer electrode 602—separated by an insulating gap and biased by different (time-dependent) voltages V₁ and V₂, respectively. (Deformation of substrate 102 is exaggerated in FIG. 6A.) For example, six (or some other number of) the inner circular electrodes in configuration 530 in FIG. 5D can be biased with voltage V₁ while six (or some other number of) outer circular electrodes can be biased with voltage V₂. Electrodes 601 and 602 apply different forces to different regions of substrate 102. Initially, when substrate 102 with the bow deformation is pulled (with electric forces caused by the applied voltages) towards chuck 110, the first voltage signal V₁(t) applied to the inner electrode 601 of chuck 110 can pull primary contact region 604 (the central portion of substrate 102, in this example), which thus makes initial contact with chuck 110. FIG. 6B illustrates schematically voltage signals applied to different electrodes of the multizonal chuck of FIG. 6A to perform chucking of a substrate with bow deformation. The first voltage signal V₁(t) can be gradually increased (e.g., to or about V_{High}, with reference to FIG. 2) causing the primary contact region 604 to securely attach to chuck 110. As secondary contact regions 606 (the edge portions of substrate 102, in this example) are being pulled closer to the outer electrode 602 of chuck 110, the second voltage signal V₂(t) can be applied to the outer electrode 602 and gradually increased (e.g., also to or about V_{High}) to ensure secure chucking of secondary contact regions 606 to chuck 110. Concurrently, the first voltage signal V₁(t) can be decreased (and, therefore, the chucking forces applied to primary contact region 604 can be reduced) to an acceptable voltage value V₁(∞), e.g., at or somewhat above value V_{Low} (with reference to FIG. 2) at which substrate 102 still maintains secure attachment to chuck 110. The second voltage signal V₂(t) can then be reduced but maintained at a level V₂(∞) that is above the value of the first voltage signal, V₂(∞)>V₁(∞). As a result, substrate 102 is chucked with stronger electric forces at the secondary contact regions 606 and weaker electric forces at the primary contact region 604.

FIG. 6C illustrates schematically substrate 102 having a dome deformation being chucked by a chuck in configuration 530 (illustrated in FIG. 5D) configured with two electrodes—inner electrode 601 and outer electrode 602—voltages V₂ and V₁, respectively. (Deformation of substrate 102 is exaggerated in FIG. 6C.) For example, six (or some other number of) outer circular electrodes in configuration 530 can be biased with voltage V₁ while six (or some other number of) inner circular electrodes can be biased with voltage V₂. Electrodes 601 and 602 apply different forces to different regions of substrate 102. Initially, when substrate 102 with the dome deformation is pulled towards chuck 110, the first voltage signal V₁(t) applied to the outer electrode 602 of chuck 110 can pull primary contact regions 604 (the outer portions of substrate 102, in this example), which thus make initial contact with chuck 110. FIG. 6D illustrates schematically voltage signals applied to different electrodes of the multizonal chuck of FIG. 6C to perform chucking of a substrate with dome deformation. The first voltage signal V₁(t) can be gradually increased (e.g., to or about V_{High}, with reference to FIG. 2) causing the primary contact regions 604 to securely attach to chuck 110. As secondary contact region 606 (the center portion of substrate 102, in this example) is being pulled closer to the outer electrode 602 of chuck 110, the second voltage signal V₂(t) can be applied to the inner electrode 601 and gradually increased (e.g., also to or about V_{High}) to ensure secure chucking of secondary contact region 606 to chuck 110. Concurrently, the first voltage signal V₁(t) can be decreased (and, therefore, the chucking forces applied to the primary contact regions 604 are reduced) to an acceptable voltage value V₁ (∞), e.g., at or somewhat above value V_{Low} (with reference to FIG. 2) at which substrate 102 still maintains secure attachment to chuck 110. The second voltage signal V₂(t) can then be reduced but maintained at a level V₂(∞) that is above the value of the first voltage signal, V₂(∞)>V₁(∞). As a result, substrate 102 is chucked with stronger electric forces at the secondary contact region 606 and weaker electric forces at the primary contact regions 604.

FIG. 6E illustrates schematically substrate 102 having a cylindrical deformation being clamped by a chuck in configuration 520 (illustrated in FIG. 5C) or a chuck in configuration 550 (illustrated in FIG. 5F). The chuck 110 can be configured with four outer electrodes 611, 612, 613, and 614, and an inner electrode 615. (Deformation of substrate 102 is exaggerated in FIG. 6E.) Outer electrodes 611, 613, and inner electrode 615 can be biased with the first voltage signal V₁(t) to pull primary contact region 604 (the central fold of substrate 102, in this example) before electrodes 612 and 614 pull the secondary contact regions 606 (the edges of substrate 102, in this example) towards chuck 110. FIG. 6F illustrates schematically voltage signals applied to different electrodes of the multizonal chuck of FIG. 6E to perform chucking of a substrate with cylindrical deformation. The first voltage signal V₁(t) can be gradually increased (e.g., to or about V_{High}, with reference to FIG. 2) causing the primary contact region 604 to securely attach to chuck 110. As the secondary contact regions 606 are being pulled closer to the electrodes 612 and 614 of chuck 110, the second voltage signal V₂(t) can be applied to the electrodes 612 and 614 and gradually increased (e.g., also to or about V_{High}) to ensure secure chucking of secondary contact region 606 to chuck 110. Concurrently, the first voltage signal V₁(t) can be decreased (and, therefore, the chucking forces applied to the primary contact regions 604 are reduced) to an acceptable voltage value V₁(∞), e.g., at or somewhat above value V_{Low} (with reference to FIG. 2) at which substrate 102 still maintains secure attachment to chuck 110. The second voltage signal V₂(t) can then be reduced but maintained at a level V₂(∞) that is above the value of the first voltage signal, V₂(∞)>V₁(∞). As a result, substrate 102 is chucked with stronger electric forces at the secondary contact regions 606 and weaker electric forces at the primary contact regions 604.

FIG. 6G illustrates schematically substrate 102 having a saddle deformation being chucked by a chuck in configuration 520 (illustrated in FIG. 5D) or a chuck in configuration 550 (illustrated in FIG. 5F). The chuck 110 can be configured with four outer electrodes 611, 612, 613, and 614, and an inner electrode 615. (Deformation of substrate 102 is exaggerated in FIG. 6E.) Outer electrodes 611 and 613 can be biased with the first voltage signal V₁(t) to pull primary contact region 604 (downward-facing edges of substrate 102, in this example) before inner electrode 615 biased with the second voltage signal V₂(t) pulls the secondary contact region 606 (the center of substrate 102, in this example), which in turn happens before electrodes 612 and 614 biased with the third voltage signal V₃(t) pull the tertiary contact regions 608 (upward-facing edges of substrate 102) towards chuck 110. FIG. 6H illustrates schematically voltage signals applied to different electrodes of the multizonal chuck of FIG. 6G to perform chucking of a substrate with saddle deformation. The first voltage signal V₁(t) can be gradually increased (e.g., to or about V_{High}, with reference to FIG. 2) causing the primary contact regions 604 to securely attach to chuck 110. As the secondary contact region 606 is being pulled closer to inter electrode 615, the second voltage signal V₂(t) can be applied to the inter electrode 615 and gradually increased (e.g., also to or about V_{High}) to ensure secure chucking of secondary contact region 606 to chuck 110. Concurrently, the first voltage signal V₁(t) can be decreased (and, therefore, the chucking forces applied to the primary contact regions 604 are reduced) to an acceptable voltage value V₁(∞), e.g., at or somewhat above value V_{Low} (with reference to FIG. 2) at which substrate 102 still maintains secure attachment to chuck 110. Similarly, as tertiary contact regions 608 are being pulled closer to the electrodes 612 and 614 of chuck 110, the third voltage signal V₃(t) can be applied to the electrodes 612 and 614 and gradually increased (e.g., also to or about V_{High}) to ensure secure chucking of tertiary contact regions 608 to chuck 110. Concurrently, the second voltage signal V₂(t) can be decreased (and, therefore, the chucking forces applied to the primary contact regions 604 are reduced) to an acceptable voltage value V₂(∞). The third voltage signal V₃(t) can then also be reduced but maintained at a level V₃(∞) that is above the value of the second voltage signal, which is in turn above the value of the first voltage signal, V₃(∞)>V₂(∞)>V₁(∞). As a result, substrate 102 is secured to chuck 110 with the strongest electric forces at the tertiary contact regions 608, weaker electric forces at secondary contact region 606, and the weakest electric forces at the primary contact regions 604.

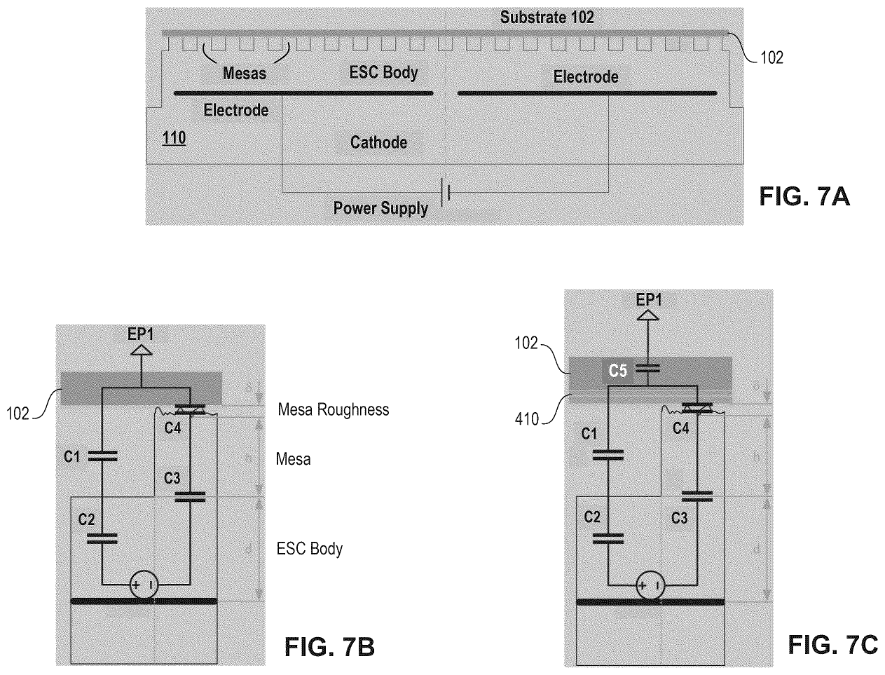

FIGS. 7A-7C illustrate a capacitance model that can be used to relate settings of an electrostatic chuck to the clamping pressure of electrostatic forces exerted on a substrate held by the electrostatic chuck, in accordance with at least one embodiment. As illustrated in FIG. 7A, a chuck 110, which can be an ESC (e.g., a Coulombic chuck, a Johnsen-Rahbek chuck, and/or the like), can have a set of protruding mesas (bumps) spaced several millimeters or one or more centimeters apart designed to prevent particle contaminants from being trapped under substrate 102 during the clamping process (and thus cause additional deformation of substrate 102). Chuck 110 can include one or more electrodes to which a set of external potentials can be delivered using one or more suitable power supply devices, e.g., a dc power supply, in some embodiments. As illustrated in FIG. 7B, clamping pressure P can be computed by determining electric fields acting within the chuck-substrate system. More specifically, a spacing between mesas can be modeled with a first capacitance C₁ (which can be determined based on the height and distance between mesas and/or modeled by solving electrostatics equations), the ESC body can be modeled with a second capacitance C₂, the combination of the mesas and the ESC body (in the location of the mesas) can be modeled with a third capacitance C₃, and surface roughness of the mesas can be modeled with a fourth capacitance C₄. In those instances where the substrate 102 has one or more films (e.g., SCL 410, oxide protective layers, etc.) deposited on a back side (or front side) of substrate 102, as illustrated in FIG. 7C, an additional fifth capacitance C₅ can be used to model these films. The charges on various capacitances C₁-C₄ (or C₁-C₅) can then be used to determine the force, and hence clamping pressure P acting on substrate 102.

The capacitance model of FIGS. 7A-7C can be used with Coulombic ESCs, e.g., aluminum oxide chucks. For applications to Johnsen-Rahbek chucks, e.g., aluminum nitride chucks, which allow leakage currents to flow through the ESC body (and mesas), the capacitance model of FIGS. 7A-7C can be augmented with resistances that are connected in parallel to capacitances C₃ and C₄ (and C₅, if applicable). In some embodiments, Johnsen-Rahbek chucks can also be modeled without the resistances (e.g., under the assumption that the leakage currents are negligibly small).

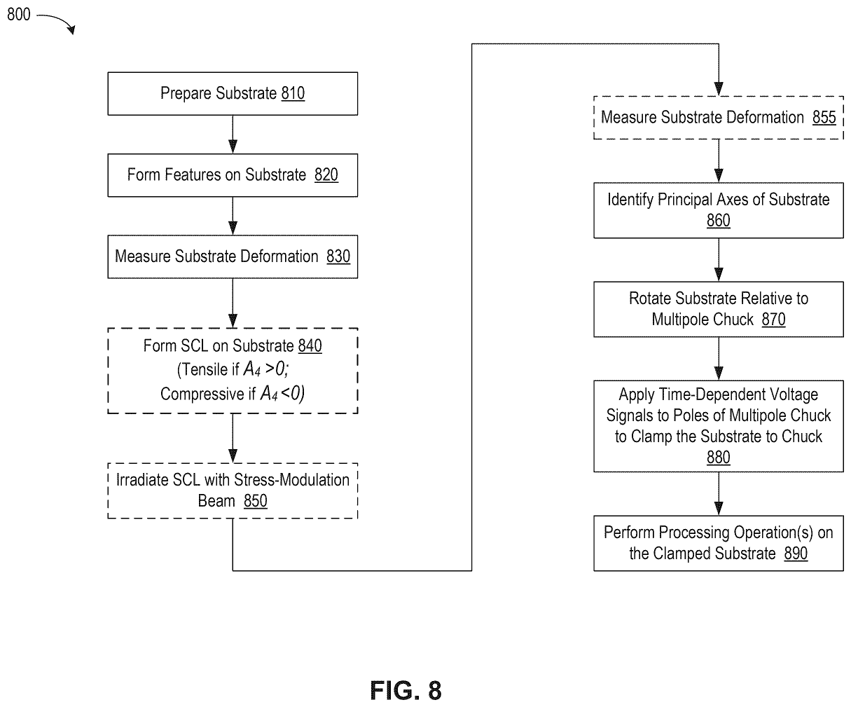

FIG. 8 is a flowchart illustrating an example method 800 of using multizonal chucks for clamping of substrates without applying excessive forces to the substrates, in accordance with at least one embodiment. Method 800 can be performed using a semiconductor manufacturing system that includes one or more processing chambers, e.g., deposition chamber(s), plasma chamber(s), etching chamber(s), polishing chamber(s), film removal chamber(s), beam irradiation chamber(s), optical inspection chamber(s), and/or the like. The processing chambers can be connected to one or more transfer chambers, which can be equipped with robot(s) to handle substrates, e.g., moving substrates into and out of processing chambers. The transfer chamber can further be connected to a load-lock chamber (Front-End Interface) that can be coupled to one or more Front Opening Unified Pod carriers that hold bare substrates, processed substrates, partially processed substrates, and/or the like. Operations performed by the semiconductor manufacturing system, including any, some or all operations of method 800, can be performed responsive to instructions issued by a suitable computing device having a processing logic and memory to store the instructions.

At block 810, method 800 can include preparing a substrate, including but not limited to obtaining a bare substrate, preprocessing the bare substrate, e.g., polishing the substrate, removing stains and/or residue from the substrate, and/or the like, and/or performing any number of similar operations. At block 820, method 800 can continue with forming one or more features on the substrate. The features can include any number of patterns, layers, films, slits, masks, holes, and/or the like. For example, the features can include a layer of a conducting material, which can include interconnect circuitry, transistors, and/or the like. In some embodiments, the features can include oxygen layers, nitrogen layers, silicon layers, germanium layers, silicon-germanium alloy layers, and/or any other suitable layers. Various layers can be used as hosts of memory cells, transistors, separations between memory cells/transistors, and/or the like. In some embodiments, the features can include various protection layers deposited, or otherwise formed, to cover other features previously formed on the substrate.

At block 830, method 800 includes identifying a deformation of the substrate, e.g., performing an optical inspection of the substrate to measure a profile of the deformation of the substrate, e.g., displacement of a surface (e.g., the bottom surface) of the substrate as a function of some suitable in-plane coordinates, e.g., polar coordinates z=s(r, φ), Cartesian coordinates, z=s(x, y), or some other coordinates.

In some embodiments, operations of block 830 include decomposing the profile of the deformation of the substrate into a plurality of harmonics, e.g., Fourier harmonics, Zernike polynomials, and/or a combination thereof. For example, the profile of the deformation can be decomposed into a parabolic bow Zernike polynomial Z₄(r, φ) and the saddle Zernike polynomials Z₅(r, φ) and Z₆(r, φ) with the rest of the profile (residual, S(x, y)) expanded over Fourier harmonics (e.g., over the Cartesian coordinates), s(r, φ)=A₄Z₄(r, φ)+A₅Z₅(r, φ)+A₆Z₆(r, φ)+S(x, y).

At optional block 840, method 800 can include forming an SCL on the substrate to cause a modification (e.g., reduction, mitigation, change of sign, etc.) of the deformation of the substrate. For example, operations of block 840 can include selecting a type of SCL to be used with the substrate. For example, such a selection can be made based on the coefficient that determines a degree of parabolicity of the deformation, e.g., coefficient A₄. If the substrate is curved downwards (towards the back side of the substrate), A₄<0, a compressive SCL can be selected for the back side deposition. If A₄>0, a tensile SCL can be selected for back side deposition. Operations of block 840 can include determining a type of a material for the SCL to be deposited and a thickness d of the SCL. In some embodiments, this determination can be made based on multiple expansion coefficients (more than just the paraboloid bow coefficient A₄) from the set {A} or the full profile h (r, φ). In one specific non-limiting example, the thickness d can selected based on a target paraboloid deformation Ã₄ sufficient to overcompensate for the measured substrate deformation.

The SCL of the selected thickness d (or some fixed thickness) can be deposited (or otherwise formed) on the substrate (e.g., as illustrated in FIG. 4B). In some embodiments, the SCL can be (or include) a silicon nitride film. The SCL can cause a modification of deformation of the substrate. In some embodiments, the SCL modification can include a reduction of the deformation (but this is not a requirement). In some embodiments, as illustrated in FIG. 4C, the SCL can overcompensate the deformation of the substrate and change the overall sign of the deformation. Although shown after block 830 in FIG. 8, operations of block 840 can also be performed before block 830 or concurrently with block 830, e.g., with measurements of the deformation performed after the SCL is formed.

In some embodiments, forming the SCL can be performed by a physical substrate deposition, chemical substrate deposition, atomic layer deposition, photoresist spin coating, optical lithography, imprint lithography, digital lithography, contact photolithography, proximity photolithography, projection photolithography, and/or other suitable techniques.

At optional block 850, method 800 can include determining, e.g., based at least on a subset of the one or more harmonics, settings of a stress-modulation beam. In some embodiments, the subset of the one or more harmonics/Zernike polynomials can include a harmonic associated with an isotropic bow deformation of the substrate and/or one or more harmonics associated with a saddle-shape deformation of the substrate. In some embodiments, the stress-modulation beam can include a beam of ions, a beam of photons, and/or a beam of electrons, or some combination thereof. The settings for the stress-modulation beam can include a type of particles of the stress-modulation beam, an energy of the particles of the stress-modulation beam, and/or an angle of incidence of the particles of the stress-modulation beam. Operations of block 850 can continue with irradiating the SCL (e.g., according to the computed irradiation doses) with a stress-modulation beam to reduce the amount of stress in the substrate and flatten the substrate (e.g., as illustrated in FIGS. 4D-4E).

At block 860, method 800 can continue with identifying one or more principal axes of the deformation of the substrate. The principal axes can include an axis of a cylindrical deformation, axes of the steepest increase and decrease of a saddle deformation, and/or the like. Identification of the principal axes can be performed, e.g., based on Zernike coefficients A₅ and A₆, for the deformation of the substrate measured at block 830 or an additional measurement (not shown in FIG. 8) performed at block 855.

At block 870, method 800 can include rotating the substrate relative to the multizonal chuck based on the one or more principal axes, e.g., to align edges of a substrate with a cylindrical deformation with electrodes 612 and 614 (or electrodes 611 and 613), as illustrated in FIG. 6E, or to align downward-facing edges of a substrate with saddle deformation with electrodes 611 and 613 and upward-facing edges of the substrate with electrodes 612 and 614, as illustrated in FIG. 6G.

At block 880, method 800 can include applying, based on the identified deformation, a plurality of time-dependent voltage signals to a multizonal chuck to attract the substrate to the multizonal chuck. Each voltage signal of the plurality of time-dependent voltage signals can be applied to one or more electrodes of the multizonal chuck. In some embodiments, the multizonal chuck can be an electrostatic chuck, e.g., Coulombic chuck, a Johnsen-Rahbek chuck, and/or the like.

In some embodiments, the multizonal electrostatic chuck can include an insulating body, and a plurality of mutually electrically isolated electrodes positioned inside the insulating body parallel to a surface of the insulating body. In some embodiments, the multizonal electrostatic chuck can also include electrical circuitry to deliver a plurality of voltage signals to the plurality of mutually electrically isolated electrodes, such that each voltage signal of the plurality of voltage signals can be delivered to one or more mutually electrically isolated electrodes. In some embodiments, the plurality of mutually electrically isolated electrodes can include two semicircular electrodes (e.g., as illustrated in FIG. 5A). In some embodiments, the plurality of mutually electrically isolated electrodes can include a plurality of concentric electrodes (e.g., as illustrated in FIG. 5D). In some embodiments, the plurality of mutually electrically isolated electrodes can include four quarter-circular electrodes or circumferentially separated electrodes (e.g., as illustrated in FIG. 5B). In some embodiments, the plurality of mutually electrically isolated electrodes can include a plurality of semi-circular ring electrodes (e.g., as illustrated in FIG. 5E). In some embodiments, the plurality of mutually electrically isolated electrodes can include a plurality of quarter-circular ring electrodes (e.g., as illustrated in FIG. 5F). In some embodiments, the multizonal chuck can include at least an inner electrode and one or more outer electrodes (e.g., as illustrated in FIG. 5C).

In some embodiments, the electrical circuitry of the multizonal electrostatic chuck can include a plurality of current detectors to detect a leakage current between the insulating body and a respective electrode of the plurality of mutually electrically isolated electrodes

In some embodiments, a first voltage signal (e.g., voltage signal V₁ in FIGS. 6B, 6D, 6F, and 6H) of the plurality of time-dependent voltage signals can include a first increasing portion and a first decreasing portion. In some embodiments, a second voltage signal (e.g., voltage signal V₂ in FIGS. 6B, 6D, 6F, and 6H) of the plurality of time-dependent voltage signals can include a second increasing portion and a second decreasing portion. The second increasing portion can be time-delayed relative to the first increasing portion (e.g., as illustrated in FIGS. 6B, 6D, 6F, and 6H).

In some embodiments, the first voltage signal can be applied to a first set of the electrodes making initial contact with the substrate (e.g., electrode 601 in FIG. 6A, electrode 602 in FIG. 6C, electrodes 611, 613, and 615 in FIG. 6E, and electrodes 611 and 613 in FIG. 6G), and the second voltage signal can be applied to a second set of the electrodes making subsequent contact with the substrate (e.g., electrode 602 in FIG. 6A, electrode 601 in FIG. 6C, electrodes 612 and 614 in FIG. 6E, and electrodes 615 in FIG. 6G). In some embodiments, the second decreasing portion can be time-delayed relative to the first decreasing portion (e.g., as illustrated in FIGS. 6B, 6D, 6F, and 6H).

In those instances where the identified deformation includes a bow deformation, the first voltage signal can be applied to the inner electrode of the multizonal chuck and the second voltage signal can be applied to the outer electrode of the multizonal chuck (e.g., as illustrated in FIGS. 6A and 6B). In those instances where the identified deformation includes a dome deformation, the first voltage signal can be applied to the outer electrode of the multizonal chuck and the second voltage signal can be applied to the inner electrode of the multizonal chuck (e.g., as illustrated in FIGS. 6C and 6D). In those instances where the identified deformation includes a cylindrical deformation, the first voltage signal can be applied to a first set of the electrodes disposed along an axis of the cylindrical deformation (e.g., electrodes 611, 613, and 615 in FIG. 6E), and the second voltage signal can be applied to a second set of the electrodes disposed near edges of the cylindrical deformation (e.g., electrodes 612 and 614 in FIG. 6E).

In those instances where the identified deformation includes a saddle deformation, a third voltage signal (e.g., voltage signal V₃ in FIG. 6H) of the plurality of time-dependent voltage signals can include a third increasing portion and a third decreasing portion. The first voltage signal can be applied to a first subset of the one or more electrodes (e.g., the subset of electrodes 611 and 613 in FIG. 6G) that is proximate to downward-facing edges of the substrate. The second voltage signal can be applied to a central electrode of the multizonal chuck (e.g., electrode 615 in FIG. 6G). The third voltage signal can be applied to a third subset of the one or more electrodes (e.g., the subset of electrodes 612 and 614 in FIG. 6G) that is proximate to upward-facing edges of the substrate. In some embodiments, the third increasing portion can be time-delayed relative to the second increasing portion (e.g., as illustrated in FIG. 6H).

At block 890, method 800 can continue with performing one or more processing operations in association with the substrate attracted to the multizonal chuck, e.g., deposition operation(s), etch operation(s), photomask placement and/or removal operation(s), cleaning operation(s), annealing operation(s), polishing operation(s), inspection operation(s), and/or the like or any combination thereof. In some embodiments, during the one or more processing operations, e.g., as illustrated in FIG. 6H, a first value of the first voltage signal can be less than a second value of the second voltage signal (V₁(∞)<V₂(∞)), which can be less than a third value of the third voltage signal (V₂(∞)<V₃(∞)).

In some embodiments, operations of blocks 840 and/or 850 can be performed as part of operations of block 890. In some embodiments, operations of blocks 840 and/or 850 can be performed both prior to operations of block 890 and as part of block 890. For example, operation of blocks 860-880 can be initially performed on a strongly deformed substrate prior to formation of an SCL on the substrate and irradiation of the SCL with a stress-modulation beam (e.g., while the substrate is clamped on the chuck). Subsequent processing operations can include removing the substrate from the chuck, cleaning the substrate, polishing the substrate, and/or the like, before repeating blocks 860-880 and performing one or more additional processing operations, e.g., deposition, masking, etching, and/or the like.

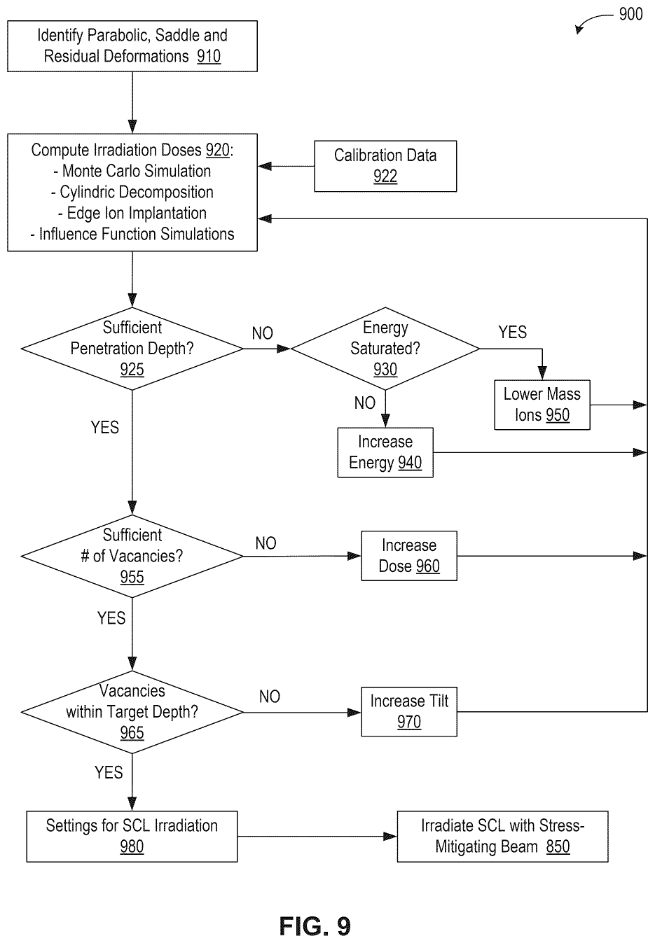

FIG. 9 is a flowchart illustrating an example method 900 of determining settings for beam irradiation, according to at least one embodiment. Method 900 can be performed as part of blocks 830-880 of method 800. At block 910, method 900 can include identifying some or all of a parabolic deformation (e.g., Zernike coefficients A₄), saddle deformation (e.g., Zernike coefficients A₅, A₆), and the residual deformation (e.g., Zernike coefficients A₇, A₈ . . . ) of a substrate, e.g., using profilometry measurements.

At block 920, method 900 can continue with computing irradiation doses n(\vec{r}) for the SCL deposited on the substrate. Operations of block 920 can include one or more techniques for determining n(\vec{r}). In some embodiments, irradiation doses n(\vec{r}) can be computed using Monte Carlo simulations. In some embodiments, irradiation doses n(\vec{r}) can be computed using cylindrical decomposition of s(\vec{r}), e.g., a decomposition of a saddle shape deformation into a parabolic deformation and a cylindrical deformation.

In some embodiments, irradiation doses n(\vec{r}) can be computed (and then applied at block 880) for selected edge regions of the SCL. For example, if the axis of cylindrical deformation is the y-axis, the edge regions can be regions located within some vicinity of points x=±R, y=0, where R is the radius of the substrate. Irradiation doses n(\vec{r}) near other regions (e.g., near the center of the substrate) can be significantly lower and/or zero, in some embodiments. In some embodiments, the edge regions of the SCL have a width that is at or below 30% of a diameter of the substrate. In some embodiments, the edge regions of the SCL can be exposed to a spatially uniform dose of particles of the stress-modulation beam, a radially-varying dose of particles of the stress-modulation beam, or an azimuthally-varying dose of particles of the stress-modulation beam. In some embodiments, irradiation doses n(\vec{r}) can be spread out more uniformly across the area of the substrate, e.g., can be non-zero both near the edges and near the middle of the substrate.

In some embodiments, irradiation doses n(\vec{r}) can be computed using an influence function G(\vec{r}; \vec{r}″), also known as the Green's function, which characterizes a response (e.g., deformation) of the substrate at a point \vec{r} of the substrate as caused by a point-like force applied at a point \vec{r}′ of the substrate. In some embodiments, the influence function G(\vec{r}; \vec{r}′) can be determined from computational simulations or analytical calculations. In some embodiments, the influence function can be determined from one or more experiments, which can include performing ion implantation into a film deposited on a reference substrate. In some embodiments, a combination of multiple techniques of determining the influence function G(\vec{r}; \vec{r}′) can be used.

As a way of example, the Monte Carlo simulations for a structure (e.g., substrate with films and an SCL deposited thereon) can be performed for specific materials of the structure (e.g., silicon substrate, stack of films, and/or the like) and for a specific thickness of the structure. An initial Monte Carlo simulation can be performed for baseline (default) conditions of beam irradiation (e.g., default settings of an ion implantation apparatus or a light-emitting apparatus). The baseline conditions can include a default type of particles (ions, photons, electrons), a default energy of particles, a default dose of particles to be directed to the SCL (e.g., a default velocity of scanning and a default scanning pattern), and the like.

In some embodiments, various techniques of irradiation dose computations can use calibration data 922 collected for actual irradiation performed for various types of the irradiation beams, energies of the irradiation beams, types and materials of structures being irradiated, angles of beam incidence on the structures, and/or the like. In some embodiments, calibration data 922 can be statistically preprocessed. For example, various measurements can be collected for multiple substrate/films/SCL materials, types of particles, angles of incidence, and/or other parameters. The statistically processed measurements can be stored (e.g., in a memory of a processing device performing computation of the irradiation doses) in the form of probability distributions of various quantities, including but not limited to:
distribution of the density of ion implantation with depth for different ion types, ion energies, angles of incidence;
distribution of the number of vacancies produced at different depths (per unit of length of travel of the ions) for different types of irradiation particles (ions, photons, electrons), particle energies, and angles of incidence;
distribution of stresses created by irradiation beams for different beam intensities and durations; and/or the like.

Performing irradiation dose computations of block 920 can include sampling from the stored distributions and identifying a likelihood that a target stress mitigation will be achieved with the default settings of conditions of beam irradiation of a SCL of a given type and thickness. Method 900 can include several verification operations designed to determine whether the target stress can be achieved without detrimentally affecting properties of the substrate/films. For example, at block 925, method 900 can include verifying if the penetration depth of the selected (e.g., default) type of particles is sufficient. For example, the penetration depth is to be at least a certain fraction of the thickness of the SCL, e.g., 20%, 30%, 50%, 80%, or more of that thickness. In some embodiments the penetration depth can be up to 100% of the thickness. If the energy is insufficient, method 900 can include checking, at block 930, if the irradiation beam source is capable of outputting particles of a higher energy. If higher energies are available, method 900 can continue with increasing the energy of the particles (block 940) and repeating irradiation dose computations of block 920 for the increased energy. If the maximum energy of the irradiation beam source has already been reached, method 900 can continue with replacing (at block 950) ions with ions of a different type (e.g., if an ion beam is used for irradiation), e.g., replacing Silicon ions with Boron, Carbon, Fluorine, etc., ions, and repeating Monte Carlo simulations for the ions of the new type.

At block 955, method 900 can include verifying whether the number of expected formed vacancies is sufficient. To verify sufficiency, method 900 can assess stress mitigation caused by formed vacancies. In one embodiment, method 900 can begin at some value of stress in the SCL, e.g., −3.0 GPa or some other suitable value (negative sign indicating compressive stress) and use beam irradiation to mitigate this stress towards a neutral point, 0.0 GPa at various locales of the SCL.

If the number of vacancies is insufficient, method 900 can include increasing a dose of particles (at block 960) and repeating irradiation dose computations of block 920 for the increased dose.

At block 965, method 900 can include verifying that the vacancies are going to be placed within a target depth, e.g., the thickness d of the film or a certain fraction of the film, such as 0.8 d, 0.7 d, 0.5 d, or some other value empirically set to prevent particles from penetrating into the substrate/films and affecting properties of the substrate/films. If the vacancies are to be formed at depths that exceed the target depth, method 900 can include (at block 970) increasing an angle of incidence (e.g., by tilting the irradiation beam) to keep vacancies (as well as substitution impurities) to a shallower region of the SCL.

Blocks 920-970 can be repeated multiple times until irradiation dose computations of block 920 are determined to be sufficient that the desired stress mitigation can be achieved, e.g., that the reduction in the tensile stress of the SCL is such that the deformation of the substrate is eliminated or at least reduced to an acceptable tolerance. The final settings for SCL irradiation (block 980) determined from irradiation dose computations can then be used for irradiation of the SCL with the stress-modulation beam (at block 850).

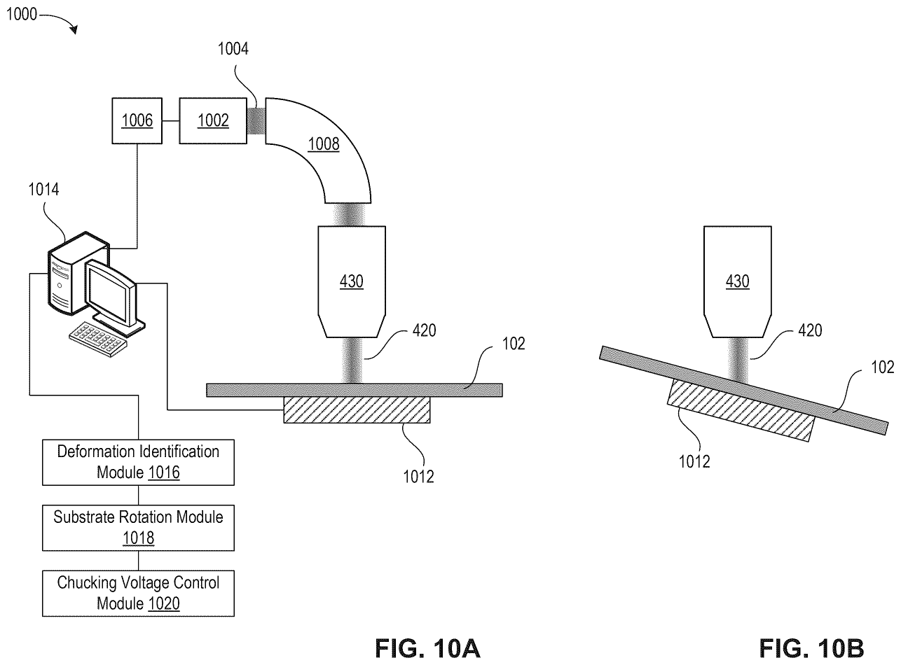

FIG. 10A illustrates schematically an irradiation system 1000 capable of performing irradiation of stress compensation layers, according to at least one embodiment. Irradiation system 1000 can include collimating and focusing column 430 of FIG. 1. Irradiation system 1000 can further include a beam source 1002 for producing a source beam 1004. Beam source 1002 can include a chamber for generating ions (e.g., a plasma chamber), a light source for generating photons (e.g., a laser, laser diode, lamp, etc.), a heated filament for producing electrons, and/or any other source for the particles of a type deployed in specific stress-modulation techniques of the instant disclosure. Beam source 1002 can be powered by a power element 1006 and can include an extraction electrode assembly (not shown). Irradiation system 1000 can include a mass spectrometer 1008 (e.g., in the instances where beam source 1002 produces charged particles, such as electrons or ions) and a collimating and focusing column 430. Collimating and focusing column 430 can direct stress-modulation beam 420 to substrate 102. Substrate 102 can be supported by a support stage 1012. In some embodiments, support stage 1012 and substrate 102 can remain stationary during irradiation of substrate 102 by stress-modulation beam 420 while components of irradiation system 1000 can be repositioned relative to substrate 102. In some embodiments, irradiation system 1000 can be stationary while support stage 1012 can reposition substrate 102. In some embodiments, stress-modulation beam 420 can have intensity (e.g., light intensity) that is modulated by changing intensity of beam source 1002 and/or placing a partially absorbing or partially reflecting material at some location between beam source 1002 and substrate 102. This enables delivery of local irradiation doses n (x, y) to various locations of substrate 102. Scanning with stress-modulation beam 420 can occur along multiple directions, e.g., along x-axis and along y-axis according to any suitable predetermined pattern, e.g., back- and forth along x-axis, in a spiral pattern, and so on. In various embodiments, stress-modulation beam 420 can be scanned with a frequency of several Hz, tens of Hz, hundreds of Hz, thousands of Hz, or more.

Operations of irradiation system 1000 can be controlled by a controller 1014, which can include any suitable computing device, microcontroller, or any other processing device having a processor, e.g., a central processing unit (CPU), a field-programmable gate array (FPGA), an application-specific integrated circuit (ASIC), and/or the like, and a memory device, e.g., a random-access memory (RAM), read-only memory (ROM), flash memory, and/or the like or any combination thereof. Controller 1014 can control operations of power element 1006, support stage 1012 (which can include a multizonal chuck), and/or various other components and modules of irradiation system 1000. Controller 1014 can include a deformation identification module 1016 capable of performing optical inspection of substrate 102, mapping of substrate's deformation, and identification of principal axes of substrate's deformation. Controller 1014 can further include a substrate rotation module 1018 capable of rotating substrate 102 relative to the multizonal chuck. Controller 1014 can also include a chucking voltage control module 1020 capable of selecting voltage signals (e.g., V₁(t), V₂(t), V₃(t), etc.) for various electrodes of the multizonal chuck, including the strength of the signals, relative time delays between the signals, and/or the like. In some embodiments, as illustrated in FIG. 10B, support stage 1012 can impart a tilt, e.g., in one or two spatial directions to substrate 102 to change an angle of incidence of stress-modulation beam 420 relative to substrate 102. In some embodiments, instead of tilting substrate 102, controller 1014 can cause a tilt of stress-modulation beam 420 relative to substrate 102.

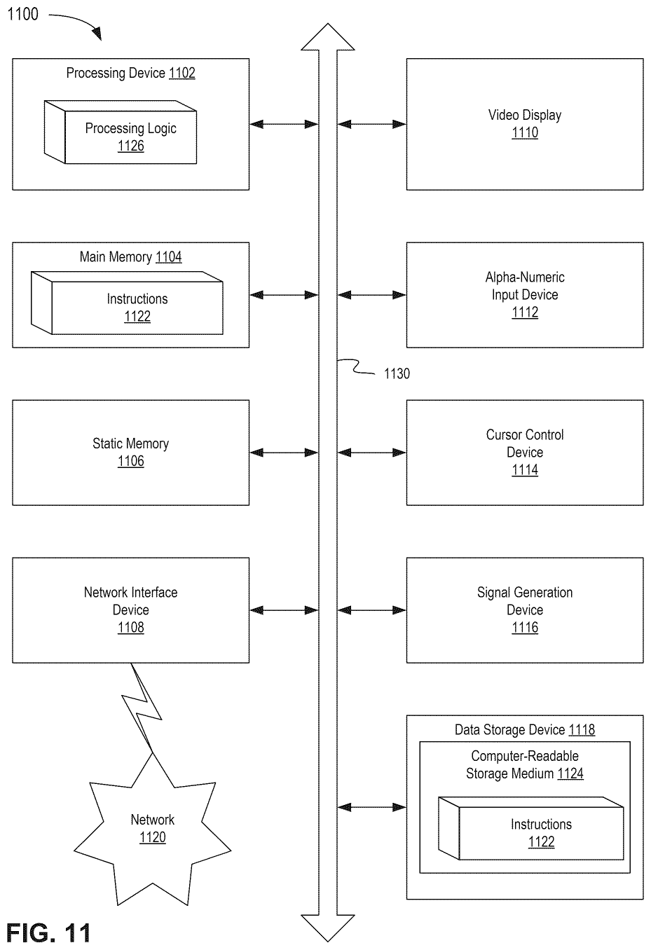

FIG. 11 depicts a block diagram of an example computer system 1100 capable of supporting operations of the present disclosure, according to at least one embodiment. In various illustrative examples, example computer system 1100 may be or include controller 1014 of FIG. 10A. Example computer system 1100 may be connected to other computer systems in a LAN, an intranet, an extranet, and/or the Internet. Computer system 1100 may operate in the capacity of a server in a client-server network environment. Computer system 1100 may be a personal computer (PC), a set-top box (STB), a server, a network router, switch or bridge, or any device capable of executing a set of instructions (sequential or otherwise) that specify actions to be taken by that device. Further, while only a single example computer system is illustrated, the term “computer” shall also be taken to include any collection of computers that individually or jointly execute a set (or multiple sets) of instructions to perform any one or more of the methods discussed herein.

Example computer system 1100 may include a processing device 1102 (also referred to as a processor or CPU), a main memory 1104 (e.g., read-only memory (ROM), flash memory, dynamic random access memory (DRAM) such as synchronous DRAM (SDRAM), etc.), a static memory 1106 (e.g., flash memory, static random access memory (SRAM), etc.), and a secondary memory (e.g., a data storage device 1118), which may communicate with each other via a bus 1130.

Processing device 1102 represents one or more general-purpose processing devices such as a microprocessor, central processing unit, or the like. More particularly, processing device 1102 may be a complex instruction set computing (CISC) microprocessor, reduced instruction set computing (RISC) microprocessor, very long instruction word (VLIW) microprocessor, processor implementing other instruction sets, or processors implementing a combination of instruction sets. Processing device 1102 may also be one or more special-purpose processing devices such as an application specific integrated circuit (ASIC), a field programmable gate array (FPGA), a digital signal processor (DSP), network processor, or the like. In accordance with one or more aspects of the present disclosure, processing device 1102 may include a processing logic 1126 configured to execute instructions (e.g., instructions 1122) implementing example method 800 of improving chucking of substrates using stress-compensation beams with multiscale irradiation doses, in accordance with at least one embodiment.

Example computer system 1100 may further comprise a network interface device 1108, which may be communicatively coupled to a network 1120. Example computer system 1100 may further comprise a video display 1110 (e.g., a liquid crystal display (LCD), a touch screen, or a cathode ray tube (CRT)), an alphanumeric input device 1112 (e.g., a keyboard), a cursor control device 1114 (e.g., a mouse), and an acoustic signal generation device 1116 (e.g., a speaker).

Data storage device 1118 may include a computer-readable storage medium (or, more specifically, a non-transitory computer-readable storage medium) 1124 on which is stored one or more sets of executable instructions 1122. In accordance with one or more aspects of the present disclosure, executable instructions 1122 may comprise executable instructions implementing example method 800 of improving chucking of substrates using stress-compensation beams with multiscale irradiation doses, in accordance with at least one embodiment.

Executable instructions 1122 may also reside, completely or at least partially, within main memory 1104 and/or within processing device 1102 during execution thereof by example computer system 1100, main memory 1104 and processing device 1102 also constituting computer-readable storage media. Executable instructions 1122 may further be transmitted or received over a network via network interface device 1108.

While the computer-readable storage medium 1124 is shown in FIG. 11 as a single medium, the term “computer-readable storage medium” should be taken to include a single medium or multiple media (e.g., a centralized or distributed database, and/or associated caches and servers) that store the one or more sets of operating instructions. The term “computer-readable storage medium” shall also be taken to include any medium that is capable of storing or encoding a set of instructions for execution by the machine that cause the machine to perform any one or more of the methods described herein. The term “computer-readable storage medium” shall accordingly be taken to include, but not be limited to, solid-state memories, and optical and magnetic media.

Some portions of the detailed descriptions above are presented in terms of algorithms and symbolic representations of operations on data bits within a computer memory. These algorithmic descriptions and representations are the means used by those skilled in the data processing arts to most effectively convey the substance of their work to others skilled in the art. An algorithm is here, and generally, conceived to be a self-consistent sequence of steps leading to a desired result. The steps are those requiring physical manipulations of physical quantities. Usually, though not necessarily, these quantities take the form of electrical or magnetic signals capable of being stored, transferred, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. Unless specifically stated otherwise, as apparent from the following discussion, it is appreciated that throughout the description, discussions utilizing terms such as “identifying,” “determining,” “storing,” “adjusting,” “causing,” “returning,” “comparing,” “creating,” “stopping,” “loading,” “copying,” “throwing,” “replacing,” “performing,” or the like, refer to the action and processes of a computer system, or similar electronic computing device, that manipulates and transforms data represented as physical (electronic) quantities within the computer system's registers and memories into other data similarly represented as physical quantities within the computer system memories or registers or other such information storage, transmission or display devices.

Examples of the present disclosure also relate to an apparatus for performing the methods described herein. This apparatus may be specially constructed for the required purposes, or it may be a general purpose computer system selectively programmed by a computer program stored in the computer system. Such a computer program may be stored in a computer readable storage medium, such as, but not limited to, any type of disk including optical disks, CD-ROMs, and magnetic-optical disks, read-only memories (ROMs), random access memories (RAMs), EPROMs, EEPROMs, magnetic disk storage media, optical storage media, flash memory devices, other type of machine-accessible storage media, or any type of media suitable for storing electronic instructions, each coupled to a computer system bus.

The methods and displays presented herein are not inherently related to any particular computer or other apparatus. Various general purpose systems may be used with programs in accordance with the teachings herein, or it may prove convenient to construct a more specialized apparatus to perform the required method steps. The required structure for a variety of these systems will appear as set forth in the description below. In addition, the scope of the present disclosure is not limited to any particular programming language. It will be appreciated that a variety of programming languages may be used to implement the teachings of the present disclosure.

It is to be understood that the above description is intended to be illustrative, and not restrictive. Many other embodiment examples will be apparent to those of skill in the art upon reading and understanding the above description. Although the present disclosure describes specific examples, it will be recognized that the systems and methods of the present disclosure are not limited to the examples described herein, but may be practiced with modifications within the scope of the appended claims. Accordingly, the specification and drawings are to be regarded in an illustrative sense rather than a restrictive sense. The scope of the present disclosure should, therefore, be determined with reference to the appended claims, along with the full scope of equivalents to which such claims are entitled.

What is claimed is:

1. A method comprising:
identifying deformation of a substrate;
applying, based on the identified deformation, a plurality of time-dependent voltage signals to a multizonal chuck to attract the substrate to the multizonal chuck, wherein each voltage signal of the plurality of time-dependent voltage signals is applied to one or more electrodes of the multizonal chuck; and
performing one or more processing operations in association with the substrate attracted to the multizonal chuck.

2. The method of claim 1, wherein the multizonal chuck comprises at least four circumferentially separated electrodes.

3. The method of claim 1, wherein the multizonal chuck comprises at least an inner electrode and one or more outer electrodes.

4. The method of claim 1, wherein a first voltage signal of the plurality of time-dependent voltage signals comprises a first increasing portion and a first decreasing portion.

5. The method of claim 4, wherein a second voltage signal of the plurality of time-dependent voltage signals comprises a second increasing portion and a second decreasing portion, wherein the second increasing portion is time-delayed relative to the first increasing portion.

6. The method of claim 5, wherein the first voltage signal is applied to a first set of the electrodes making initial contact with the substrate, and wherein the second voltage signal is applied to a second set of the electrodes making subsequent contact with the substrate.

7. The method of claim 5, wherein the second decreasing portion is time-delayed relative to the first decreasing portion, and wherein, during the one or more processing operations, a first value of the first voltage signal is less than a second value of the second voltage signal.

8. The method of claim 5, wherein the identified deformation comprises at least one of:
a bow deformation, or
a dome deformation;
wherein the first voltage signal is applied to at least one of:
an inner electrode of the multizonal chuck, or
an outer electrode of the multizonal chuck; and
wherein the second voltage signal is applied to another one of:
the inner electrode of the multizonal chuck, or
the outer electrode of the multizonal chuck.

9. The method of claim 5, wherein the identified deformation comprises a cylindrical deformation, wherein the first voltage signal is applied to a first set of the electrodes disposed along an axis of the cylindrical deformation, and wherein the second voltage signal is applied to a second set of the electrodes disposed near edges of the cylindrical deformation.

10. The method of claim 5, wherein the identified deformation comprises a saddle deformation, wherein a third voltage signal of the plurality of time-dependent voltage signals comprises a third increasing portion and a third decreasing portion, wherein the first voltage signal is applied to a first subset of the one or more electrodes that is proximate to downward-facing edges of the substrate, wherein the second voltage signal is applied to a central electrode of the multizonal chuck, wherein the third voltage signal is applied to a third subset of the one or more electrodes that is proximate to upward-facing edges of the substrate, and wherein the third increasing portion is time-delayed relative to the second increasing portion.

11. The method of claim 1, wherein identifying deformation of the substrate comprises:
performing optical inspection of the substrate.

12. The method of claim 1, further comprising:
identifying one or more principal axes of the deformation of the substrate; and
rotating the substrate relative to the multizonal chuck based on the one or more principal axes.

13. The method of claim 1, further comprising:
prior to applying the plurality of time-dependent voltage signals to the multizonal chuck to attract the substrate to the multizonal chuck:
forming a stress-compensation layer (SCL) on the substrate, wherein the SCL causes a modification of the deformation of the substrate; and
irradiating the SCL with a stress-modulation beam that causes reduction of the deformation of the substrate.

14. An electrostatic chuck comprising:
an insulating body;
a plurality of mutually electrically isolated electrodes positioned inside the insulating body parallel to a surface of the insulating body; and
electrical circuitry to deliver a plurality of voltage signals to the plurality of mutually electrically isolated electrodes, each voltage signal of the plurality of voltage signals delivered to one or more mutually electrically isolated electrodes of the plurality of mutually electrically isolated electrodes.

15. The electrostatic chuck of claim 14, wherein the plurality of mutually electrically isolated electrodes comprises at least one of:
two semicircular electrodes, or
four quarter-circular electrodes.

16. The electrostatic chuck of claim 14, wherein the plurality of mutually electrically isolated electrodes comprises a plurality of concentric electrodes.

17. The electrostatic chuck of claim 14, wherein the plurality of mutually electrically isolated electrodes comprises at least one of:
a plurality of semi-circular ring electrodes, or
a plurality of quarter-circular ring electrodes.

18. The electrostatic chuck of claim 14, wherein the electrical circuitry comprises a plurality of current detectors, each of the current detectors to detect a leakage current between the insulating body and a respective electrode of the plurality of mutually electrically isolated electrodes.

19. A semiconductor manufacturing system comprising one or more processing chambers, the semiconductor manufacturing system to:
identify deformation of a substrate;
apply, based on the identified deformation, a plurality of time-dependent voltage signals to a multizonal chuck to attract the substrate to the multizonal chuck located in a processing chamber of the one or more processing chambers, wherein each voltage signal of the plurality of time-dependent voltage signals is applied to one or more electrodes of the multizonal chuck; and
perform one or more processing operations in association with the substrate attracted to the multizonal chuck.

20. The semiconductor manufacturing system of claim 19, wherein a first voltage signal of the plurality of time-dependent voltage signals comprises a first increasing portion and a first decreasing portion, wherein a second voltage signal of the plurality of time-dependent voltage signals comprises a second increasing portion and a second decreasing portion, and wherein the second increasing portion is time-delayed relative to the first increasing portion.
